(19) United States
(12) Patent Application Publication
(10) Pub. No.: US 2026/0150479 A1
(43) Pub. Date: May 28, 2026

(54) SENSOR, IMAGE SENSOR, DISPLAY PANEL, AND DEVICE

(71) Applicants: Samsung Electronics Co., Ltd., Suwon-si (KR); UIF (University Industry Foundation), Yonsei University, Seoul (KR)

(72) Inventors: Jeoung In YI, Suwon-si (KR); Hyerim HONG, Suwon-si (KR); Tae Jin CHOI, Suwon-si (KR); Sungyoung YUN, Suwon-si (KR); Feifei FANG, Suwon-si (KR); Jeong Il PARK, Suwon-si (KR); Sang Ho PARK, Suwon-si (KR); Kyung Bae PARK, Suwon-si (KR); Woojae KIM, Seoul (KR); Dongho KIM, Seoul (KR)

(73) Assignees: Samsung Electronics Co., Ltd., Suwon-si (KR); UIF (University Industry Foundation), Yonsei University, Seoul (KR)

(21) Appl. No.: 19/397,010

(22) Filed: Nov. 21, 2025

(30) Foreign Application Priority Data
Nov. 26, 2024 (KR) 10-2024-0171408
Dec. 27, 2024 (KR) 10-2024-0199311
Nov. 17, 2025 (KR) 10-2025-0173137

(51) Int. Cl. H10K 30/85; H10K 39/34; H10K 85/60

(52) U.S. Cl. CPC H10K 30/85; H10K 39/34; H10K 85/622; H10K 85/655

(57) ABSTRACT

A sensor includes an anode; a cathode; an organic photoelectric conversion layer between the anode and the cathode; and a first organic auxiliary layer between the anode and the organic photoelectric conversion layer, the organic photoelectric conversion layer includes a p-type semiconductor and an n-type semiconductor, and the first organic auxiliary layer includes a first singlet fission material represented by Chemical Formula 1 and satisfying Relation Formula 1:

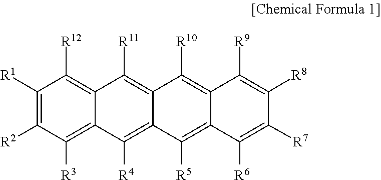

$$E ( {S}_{1} ) + 0.5 eV \geq 2 \times E ( {T}_{1} ) \qquad [ Relation Formula 1 ]$$

wherein, Chemical Formula 1 and Relation Formula 1 are the same as described in the specification.

### CROSS-REFERENCE TO RELATED APPLICATIONS

This application claims priority to and the benefit of Korean Patent Application Nos. 10-2024-0171408, 10-2024-0199311, and 10-2025-0173137, filed with the Korean Intellectual Property Office on Nov. 26, 2024, Dec. 27, 2024, and Nov. 17, 2025, respectively, and the entire contents of each of which are incorporated herein by reference.

### BACKGROUND

Example embodiments are directed to sensors, image sensors, display panels, and devices.

A photoelectric conversion device is a device that absorbs light and converts the absorbed light into an electrical signal, and is applied to various fields that require optical properties. Silicon is a representative photoelectric conversion material configured to absorb light and convert the absorbed light into an electrical signal, and may be used with a color filter to exhibit wavelength selectivity. Photoelectric conversion devices may be used as sensors due to their photoelectric conversion characteristics and wavelength selectivity.

### SUMMARY

Recently, in order to increase a resolution of sensors, it is required to integrate many pixels per unit area. Accordingly, the size of each pixel becomes smaller, and as a result, the absorption area of silicon within each pixel is not sufficient, which limits the ability to achieve high sensitivity.

Some example embodiments provide a sensor with high integration and high sensitivity characteristics.

Some example embodiments provide an image sensor including the sensor.

Some example embodiments provide a display panel including the sensor.

Some example embodiments provide a device including the sensor, the image sensor, or the display panel.

According to some example embodiments, a sensor includes an anode, a cathode, an organic photoelectric conversion layer between the cathode and the anode, and a first organic auxiliary layer between the anode and the organic photoelectric conversion layer. The organic photoelectric conversion layer may include a p-type semiconductor and an n-type semiconductor. The first organic auxiliary layer may include a first singlet fission material represented by Chemical Formula 1 and satisfying Relation Formula 1:

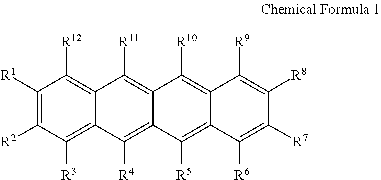

wherein, in the Chemical Formula 1,
R¹ to R¹² may each independently be hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heteroaryl group, a substituted or unsubstituted silyl group, a substituted or unsubstituted amine group, a halogen, a cyano group, or any combination thereof, provided that at least one of R¹ to R¹² may be represented by Chemical Formula 2:

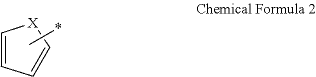

wherein, in the Chemical Formula 2,
X may be oxygen (O), sulfur (S), or tellurium (Te), and
* is a linking point with Chemical Formula 1; and

$$E ( {S}_{1} ) + 0.5 eV \geq 2 \times E ( {T}_{1} ) \qquad Relation Formula 1$$

wherein, in Relation Formula 1,
E(S₁) is an excitation energy in a lowest singlet excited state of the first singlet fission material,
E(T₁) is an excitation energy in a lowest triplet excited state of the first singlet fission material, and
E(S₁) and E(T₁) are Density Function Theory (DFT) calculation values.

The first singlet fission material may have a highest occupied molecular orbital (HOMO) energy level that is a same or shallower energy relative to a HOMO energy level of the p-type semiconductor.

The first organic auxiliary layer may be in contact with the organic photoelectric conversion layer.

The HOMO energy level of the first singlet fission material may be between the HOMO energy level of the p-type semiconductor and a work function of the anode.

The first singlet fission material and at least one of the p-type semiconductor or the n-type semiconductor may be each a wavelength selective organic material configured to selectively absorb light of a first wavelength spectrum selected from a blue wavelength spectrum, a green wavelength spectrum, a red wavelength spectrum, or an infrared wavelength spectrum.

In Chemical Formula 1, at least one of R³ to R⁶ and at least one of R⁹ to R¹² may, each independently, be represented by Chemical Formula 2. Alternatively, in Chemical Formula 1, at least one of R¹ and R² and at least one of R⁷ to R⁸ may, each independently, be represented by Chemical Formula 2.

The first singlet fission material may be represented by any one of Group 1:

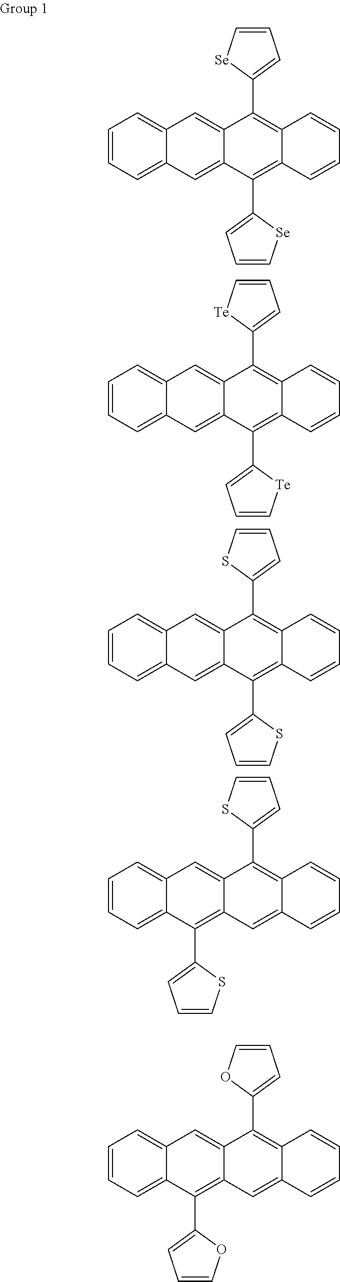

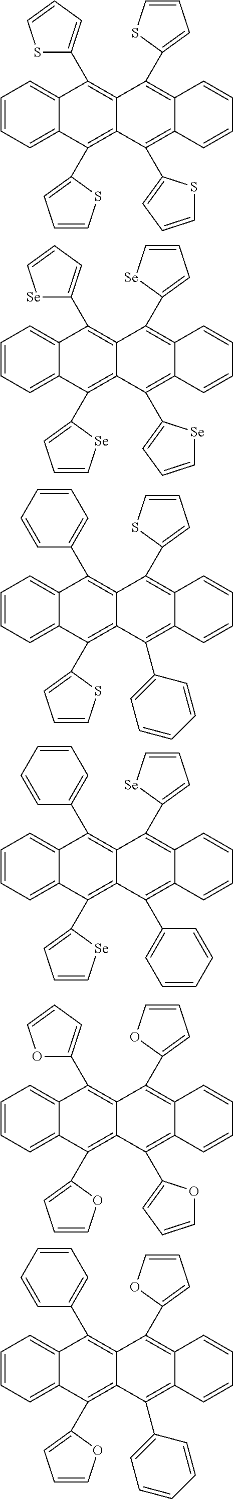

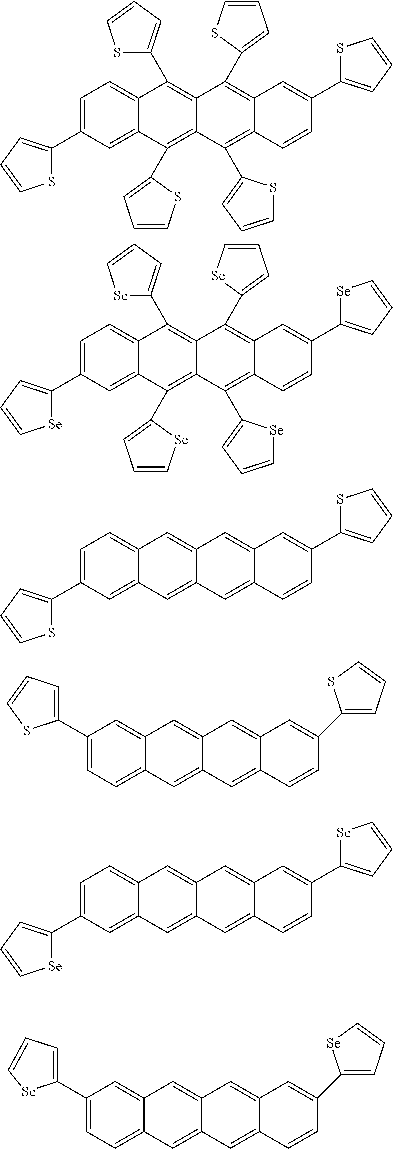

The sensor may further include a hole auxiliary layer between the first organic auxiliary layer and the anode, and a lowest unoccupied molecular orbital (LUMO) energy level of the hole auxiliary layer may be a shallower energy relative to a work function of the anode and the LUMO energy level of the n-type semiconductor.

The sensor may further include a second organic auxiliary layer between the cathode and the organic photoelectric conversion layer, wherein the second organic auxiliary layer may include a second singlet fission material different from the first singlet fission material.

The second organic auxiliary layer may be in contact with the organic photoelectric conversion layer, and a LUMO energy level of the second singlet fission material may be a same or deeper energy level relative to a LUMO energy level of the n-type semiconductor.

The LUMO energy level of the second singlet fission material may be between the LUMO energy level of the n-type semiconductor and a work function of the cathode.

The sensor may further include an electron auxiliary layer between the second organic auxiliary layer and the cathode, and a HOMO energy level of the electron auxiliary layer may be a deeper energy level relative to a work function of the cathode and the HOMO energy level of the p-type semiconductor.

According to some example embodiments, an image sensor may include a substrate, and the sensor on the substrate.

The image sensor may further include a first photodiode and a second photodiode within the substrate, wherein the first photodiode and the second photodiode may each overlap the sensor along a thickness direction of the substrate.

The image sensor may further include a first color filter between the sensor and the first photodiode in the thickness direction, and a second color filter between the sensor and the second photodiode in the thickness direction.

The sensor may include a first sensor configured to photoelectrically convert light of a first wavelength spectrum selected from a red wavelength spectrum, a green wavelength spectrum, and a blue wavelength spectrum, a second sensor configured to photoelectrically convert light of a second wavelength spectrum selected from the red wavelength spectrum, the green wavelength spectrum, and the blue wavelength spectrum, and a third sensor configured to photoelectrically convert light of a third wavelength spectrum selected from the red wavelength spectrum, the green wavelength spectrum, and the blue wavelength spectrum, wherein the first wavelength spectrum, the second wavelength spectrum, and the third wavelength spectrum may be different from each other, and wherein the first sensor, the second sensor, and the third sensor may be stacked along a thickness direction of the substrate.

According to some example embodiments, a display panel may include a substrate, a light emitting element array on the substrate, the light emitting element array including a blue light emitting element configured to emit light in a blue wavelength spectrum, a green light emitting element configured to emit light in a green wavelength spectrum, and a red light emitting element configured to emit light in a red wavelength spectrum, and a sensor array on the substrate, the sensor array including the sensor.

According to some example embodiments, a device including the sensor, the image sensor, or the display panel is provided.

Sensitivity of the sensor may be increased while reducing the size of the sensor.

### BRIEF DESCRIPTION OF THE DRAWINGS

FIG. 1 is a cross-sectional view showing a sensor according to some example embodiments,

FIG. 2 is a cross-sectional view showing a sensor according to some example embodiments,

FIG. 3 is a cross-sectional view showing a sensor according to some example embodiments,

FIG. 4 is a cross-sectional view showing a sensor according to some example embodiments,

FIG. 5 is a cross-sectional view showing an image sensor according to some example embodiments,

FIG. 6 is a plan view showing an image sensor according to some example embodiments,

FIG. 7 is a cross-sectional view taken along the I-I line of FIG. 6 according to some example embodiments,

FIG. 8 is a cross-sectional view taken along the I-I line of FIG. 6 according to some example embodiments,

FIG. 9 is a plan view showing an image sensor according to some example embodiments,

FIG. 10 is a cross-sectional view taken along the II-II line of FIG. 9 according to some example embodiments,

FIG. 11 is a plan view showing a sensor-embedded display panel according to some example embodiments,

FIG. 12 is a cross-sectional view showing a sensor-embedded display panel taken along the III-III line of FIG. 11 according to some example embodiments,

FIG. 13 is a schematic view showing a smart phone as an electronic device according to some example embodiments,

FIG. 14 is a schematic view illustrating an electronic device according to some example embodiments,

FIG. 15 is a schematic view showing an optical communication device as an electronic device according to some example embodiments,

FIG. 16 shows graphs of the absorption spectra and photoluminescence (PL) spectra of rubrene (4P-Tc), and 2T-Tc and 4T-Tc, prepared in Synthesis Examples 1 and 2, respectively, in solution state and in thin films,

FIGS. 17A through 17D show graphs representing the results of simulations of molecular dynamics (MD) of Rubrene (4P-Tc), and 2T-Tc and 4T-Tc, prepared in Synthesis Examples 1 and 2, respectively, and specifically, FIG. 17A shows radical distribution functions between the center-of-mass coordinates of the materials, FIG. 17B shows probability distribution of backbone twist angle of the materials in the Mechanical Dynamics simulation results, FIG. 17C and FIG. D show distribution plots as a function of inter-tetracene angle and center-of-mass distance between neighboring molecules for 2T-Tc and 4T-Tc, respectively,

FIG. 18 and FIG. 19 show graphs representing the results of femtosecond transient absorption (fs-TA) of the thermally evaporated thin films of Rubrene (4P-Tc), 2T-Tc, and 4T-Tc,

FIG. 20 shows absorbance tracing results monitoring at the peak of 0-0 transition from S₀ to S₁ for Rubrene (4P-Tc), 2T-Tc, and 4T-Tc, respectively, in ambient-air exposed films and encapsulated films, and

FIG. 21 is photographs of thin films of Rubrene (4P-Tc), 2T-Tc, and 4T-Tc took under different experimental conditions.

### DETAILED DESCRIPTION

Hereinafter, some example embodiments of the present inventive concepts will be described in detail so that a person skilled in the art would understand the same. However, the inventive concepts may be embodied in many different forms and is not to be construed as limited to the example embodiments set forth herein.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity, and the same or similar constituent elements are indicated by the same reference numeral throughout the specification.

Hereinafter, the terms “lower portion” and “upper portion” are for convenience of description and do not limit the positional relationship.

As used herein, “Cx-Cy” or “Cx to Cy” refers that a number (e.g., quantity) of carbons constituting a substituent is x to y, wherein x and y may each be any natural number. For example, “C1-C6” and “C1 to C6” means that a number of carbons constituting the substituent is 1 to 6, and “C6-C20” and C6 to C20” means that a number of carbons constituting the substituent is 6 to 20.

The term “divalent hydrocarbon group” as used herein refers to a divalent moiety, in which any one hydrogen of the monovalent hydrocarbon group is replaced by a bonding site with an adjacent atom. The divalent hydrocarbon group may include, for example, a linear or branched alkylene group, a cycloalkylene group, an alkenylene group, an alkynylene group, a cycloalkylene group, an arylene group, groups in which some carbon atoms of the aforementioned groups are replaced by heteroatoms, and the like.

The term “alkyl group” as used herein refers to a linear or branched saturated aliphatic hydrocarbon monovalent group, and specific examples thereof include a methyl group, an ethyl group, a propyl group, an isobutyl group, a sec-butyl group, a tert-butyl group, a pentyl group, an iso-amyl group, a hexyl group, and the like. The term “alkylene group” as used herein refers to a linear or branched saturated aliphatic hydrocarbon divalent group, and specific examples thereof include a methylene group, an ethylene group, a propylene group, a butylene group, an isobutylene group, and the like.

The term “alkoxy group” as used herein refers to a monovalent group having a formula of —OA101, wherein A101 is an alkyl group. Specific examples thereof include a methoxy group, an ethoxy group, an isopropyloxy group, and the like.

The term “cycloalkyl group” as used herein refers to a monovalent saturated hydrocarbon cyclic group, and specific examples thereof include monocyclic groups such as a cyclopropyl group, a cyclobutyl group, a cyclopentyl group, a cyclohexyl group, a cycloheptyl group, and the like, and polycyclic condensed cyclic groups such as a norbornyl group, and an adamantyl group. The term “cycloalkylene group” as used herein refers to a divalent saturated hydrocarbon cyclic group, and specific examples thereof include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “alkenyl” as used herein as used herein refers to a linear or branched unsaturated aliphatic hydrocarbon monovalent group including one or more carbon-carbon double bonds. The term “alkenylene group” as used herein refers to a linear or branched unsaturated aliphatic hydrocarbon divalent group including at least one carbon-carbon double bond.

The term “cycloalkenyl group” as used herein refers to a monovalent unsaturated hydrocarbon cyclic group including one or more carbon-carbon double bonds. The term “cycloalkenylene group” as used herein refers to a divalent unsaturated hydrocarbon cyclic group including one or more carbon-carbon double bonds.

As used herein, the term “arylene group” refers to a divalent group having a carbocyclic aromatic system.

The term “heteroaryl group” as used herein refers to a monovalent group having a heterocyclic aromatic system, and specific examples include a pyridinyl group, a pyrimidinyl group, a pyrazinyl group, and the like. The term “heteroarylene group” as used herein refers to a divalent group having a heterocyclic aromatic system.

As used herein, the term “arylalkyl group” refers to a group in which a monovalent group having a carbocyclic aromatic system is substituted for an alkyl group, and specific examples thereof include a benzyl group, a diphenylmethyl group, and the like.

In this specification, the term “heterocyclic group” refers to a C1-C60 monocyclic or polycyclic group including at least one heteroatom and is a group including all of monovalent, divalent, and trivalent groups.

As used herein, when a definition is not otherwise provided, “substituted” refers to replacement of a hydrogen atom of a compound by a substituent selected from a halogen atom, a hydroxyl group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, phosphoric acid or a salt thereof, a silyl group, a C1 to C20 alkyl group, a C2 to C20 alkenyl group, a C2 to C20 alkynyl group, a C6 to C30 aryl group, a C7 to C30 arylalkyl group, a C1 to C30 alkoxy group, a C1 to C20 heteroalkyl group, a C3 to C20 heteroaryl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, and any combination thereof.

As used herein, when a definition is not otherwise provided, “hetero” refers to one including 1 to 4 heteroatoms selected from N, O, S, Se, Te, Si, and P.

Hereinafter, “combination” refers to a mixture of two or more and a stack structure of two or more.

It will further be understood that when an element is referred to as being “on” another element, it may be above or beneath or adjacent (e.g., horizontally adjacent) to the other element. It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%). Elements and/or properties thereof (e.g., structures, surfaces, directions, or the like) that are “substantially parallel” with regard to other elements and/or properties thereof will be understood to be “parallel” with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%). Elements and/or properties thereof (e.g., structures, surfaces, directions, or the like) that are “substantially coplanar” with regard to other elements and/or properties thereof will be understood to be “coplanar” with regard to the other elements and/or properties thereof within manufacturing tolerances and/or material tolerances and/or have a deviation in magnitude and/or angle from “coplanar,” or the like with regard to the other elements and/or properties thereof that is equal to or less than 10% (e.g., a. tolerance of ±10%).

It will be understood that elements and/or properties thereof may be recited herein as being “identical” to, “the same” or “equal” as other elements and/or properties, and it will be further understood that elements and/or properties thereof recited herein as being “identical” to, “the same” as, or “equal” to other elements and/or properties may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances.

Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element or value is referred to as being the same as another element or value, it should be understood that an element or a value is the same as another element or value within a desired manufacturing or operational tolerance range (e.g., ±10%).

It will be understood that elements and/or properties thereof described herein as being the “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value include a tolerance of ±10% around the stated numerical value. Moreover, when the words “about” and “substantially” are used in connection with geometric shapes, it is intended that precision of the geometric shape is not required but that latitude for the shape is within the scope of the inventive concepts. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

Hereinafter, when a definition is not otherwise provided, the energy level is the highest occupied molecular orbital (HOMO) energy level or the lowest unoccupied molecular orbital (LUMO) energy level.

Hereinafter, when a definition is not otherwise provided, a work function or an energy level is expressed as an absolute value from a vacuum level. In addition, when the work function or the energy level is referred to be deep, high, or large, it may have a large absolute value based on “0 eV” of the vacuum level while when the work function or the energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-3 (Riken Keiki Co., Ltd.).

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level.

Hereinafter, a sensor according to some example embodiments will be described.

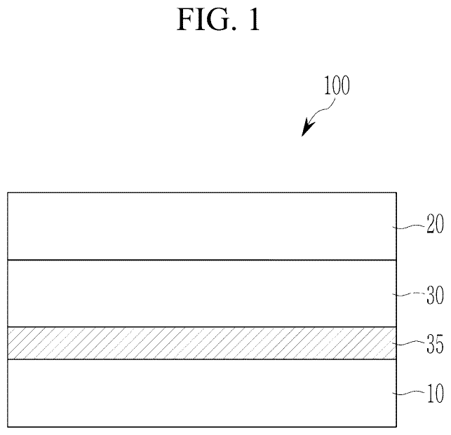

FIG. 1 is a cross-sectional view showing an example of a sensor according to some example embodiments.

Referring to FIG. 1, the sensor 100 according to some example embodiments includes an anode 10, a cathode 20, a photoelectric conversion layer 30, and a first organic auxiliary layer 35.

A substrate (not shown) may be disposed under the anode 10 or on the cathode 20. The substrate may be, for example, an inorganic substrate such as glass; a polymer substrate including polycarbonate, polymethyl methacrylate, polyethylene terephthalate, polyethylene naphthalate, polyimide, polyamide, polyamidoimide, polyethersulfone, or combinations thereof; or a semiconductor substrate such as a silicon wafer or semiconductor compound. The substrate may be omitted.

At least one of the anode 10 or the cathode 20 may be a light transmitting electrode. The transparent electrode may be a transparent electrode or a semi-transmissive electrode. The transparent electrode may have a light transmittance of about 85% to about 100%, about 90% to about 100%, or about 95% to about 100% for light in the visible light wavelength region (where a wavelength region may be referred to herein interchangeably as a wavelength range), and the semi-transmissive electrode may have a light transmittance of greater than or equal to about 30% and less than about 85%, about 40% to about 80%, or about 40% to about 75% of light in the visible light wavelength region. The transparent electrode and the semi-transmissive electrode may include, for example, at least one of an oxide conductor, a carbon conductor, or a metal thin film. The oxide conductors may include, for example, one or more of indium tin oxide (ITO), indium zinc oxide (IZO), zinc tin oxide (ZTO), aluminum tin oxide (ATO), or aluminum zinc oxide (AZO), the carbon conductor may include one or more selected from graphene and carbon nanostructures, and the metal thin film may be a very thin film including aluminum (Al), magnesium (Mg), silver (Ag), gold (Au), magnesium-silver (Mg—Ag), magnesium-aluminum (Mg-AI), an alloy thereof, or any combination thereof.

One of the anode 10 or the cathode 20 may be a reflective electrode. For example, the reflective electrode may have a low light transmittance of less than about 10% (e.g., 0% to about 10%, about 0.1% to about 10%, about 1% to about 10%, etc.) and/or a high reflectance of greater than or equal to about 50% (e.g., about 50% to about 100%, about 50% to about 90%, about 50% to about 80%, etc.) for light in the visible light wavelength range. The reflective electrode may include an optically opaque material, such as a metal, a metal alloy, a nitride thereof, or any combination thereof, for example aluminum (Al), silver (Ag), gold (Au), titanium (Ti), an alloy thereof, a nitride thereof, or any combination thereof.

For example, the anode 10 may be a light transmitting electrode and the cathode 20 may be a light transmitting electrode or a reflective electrode. For example, the anode 10 may be a light-receiving electrode or an incident electrode disposed on the side where light enters.

The photoelectric conversion layer 30 is between the anode 10 and the cathode 20.

The photoelectric conversion layer 30 may be configured to absorb light of a portion of the wavelength spectrum and convert the absorbed light into an electrical signal, and for example, the photoelectric conversion layer 30 may be configured to selectively absorb light of one wavelength spectrum selected from the red wavelength spectrum, the green wavelength spectrum, the blue wavelength spectrum, or the infrared wavelength spectrum and convert the absorbed light into an electrical signal. Herein, selectively absorbing light of one wavelength spectrum selected from the red wavelength spectrum, the green wavelength spectrum, the blue wavelength spectrum, or the infrared wavelength spectrum means that the peak absorption wavelength (λ_{peak,A}) of the absorption spectrum exists in one of about 600 nm to about 700 nm (red wavelength spectrum), about 500 nm to about 600 nm (green wavelength spectrum), about 380 nm to about 500 nm (blue wavelength spectrum), and/or about 700 nm or to about 3000 nm (infrared wavelength spectrum) and a light absorption amount within the corresponding wavelength spectrum is significantly higher than a light absorption amount in the other wavelength spectrum. The significantly higher light absorption amount of the wavelength spectrum may mean that an area of the absorption spectrum in the corresponding wavelength spectrum based on a total area of the absorption spectrum is for example greater than or equal to about 70%, greater than or equal to about 75%, greater than or equal to about 80%, greater than or equal to about 85%, greater than or equal to about 90%, or greater than or equal to about 95%.

The photoelectric conversion layer 30 may include at least one p-type semiconductor and at least one n-type semiconductor forming a pn junction, and at least one p-type semiconductor and at least one n-type semiconductor may receive light from the outside (e.g., an external environment external to the sensor 100) to generate excitons and then separate the generated excitons into holes and electrons. At least one of the p-type semiconductor or the n-type semiconductor may be an organic material, and accordingly, the photoelectric conversion layer 30 may be an organic photoelectric conversion layer.

At least one of the p-type semiconductor or the n-type semiconductor may be a light absorbing material. For example, each of the p-type semiconductor and the n-type semiconductor may be a light absorbing material. At least one of the p-type semiconductor or the n-type semiconductor may be an organic light absorption material. For example, each of the p-type semiconductor and the n-type semiconductor may be an organic light absorption material.

For example, at least one of the p-type semiconductor or the n-type semiconductor may be a wavelength-selective light absorbing material configured to selectively absorb light in a particular (or, alternatively, predetermined) wavelength regions. For example, at least one of the p-type semiconductor or the n-type semiconductor may be a wavelength-selective organic light-absorbing material. The p-type semiconductor and the n-type semiconductor may have peak absorption wavelengths (λ_{peak,A}) in the same or different wavelength regions.

As an example, the p-type semiconductor may be an organic material with a core structure including an electron donating moiety and an electron accepting moiety. As an example, the p-type semiconductor may be an organic material with a core structure that includes an electron donating moiety and an electron accepting moiety and additionally includes a π-conjugation linking group linking the electron donating moiety and the electron accepting moiety.

For example, the p-type semiconductor may be represented by Chemical Formula A or B, but is not limited thereto.

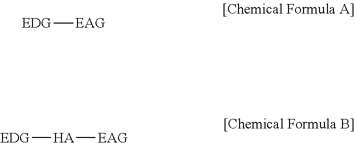

In Chemical Formulas A and B,
EDG may be an electron donating group,
EAG may be an electron accepting group, and
HA may be a π-conjugation linking group, and may be, for example, a substituted or unsubstituted C6 to C20 arylene group or a C2 to C30 heterocyclic group having at least one of S, Se, Te, or Si.

For example, the p-type semiconductor may be represented by Chemical Formula B-1.

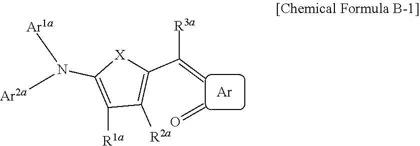

In Chemical Formula B-1,
X may be CR′═CR″, S, Se, Te, SO, SO₂, or SiR^{a}R^{b},
Ar may be a substituted or unsubstituted C6 to C30 arylene group, a substituted or unsubstituted C3 to C30 heterocyclic group, or a fused ring of the foregoing two or more,
Ar^{1a} and Ar^{2a} may each independently be a substituted or unsubstituted C6 to C30 aryl group or a substituted or unsubstituted C3 to C30 heteroaryl group,
R^{1a} to R^{3a}, R′, R″, R^{a}, and R^{b} may each independently be hydrogen, deuterium, a substituted or unsubstituted C1 to C30 alkyl group, a substituted or unsubstituted C6 to C30 aryl group, a substituted or unsubstituted C3 to C30 heteroaryl group, a substituted or unsubstituted C1 to C30 alkoxy group, a halogen, or a cyano group, and
Ar^{1a}, Ar^{2a}, R^{1a} and R^{2a} may each be independently present or two adjacent ones of Ar^{1a}, Ar^{2a}, R^{1a} and R^{2a} may be linked to each other to form a ring.

For example, in Chemical Formula B-1, Ar^{1a} and Ar^{2a} may each independently be one of a substituted or unsubstituted phenyl group, a substituted or unsubstituted naphthyl group, a substituted or unsubstituted anthracenyl group, a substituted or unsubstituted phenanthrenyl group, a substituted or unsubstituted pyridinyl group, a substituted or unsubstituted pyridazinyl group, a substituted or unsubstituted pyrimidinyl group, a substituted or unsubstituted pyrazinyl group, a substituted or unsubstituted quinolinyl group, a substituted or unsubstituted isoquinolinyl group, a substituted or unsubstituted naphthyridinyl group, a substituted or unsubstituted cinnolinyl group, a substituted or unsubstituted quinazolinyl group, a substituted or unsubstituted phthalazinyl group, a substituted or unsubstituted benzotriazinyl group, a substituted or unsubstituted pyridopyrazinyl group, a substituted or unsubstituted pyridopyrimidinyl group, or a substituted or unsubstituted pyridopyridazinyl group.

As an example, two adjacent ones of Ar^{1a}, Ar^{2a}, R^{1a} and R^{2a} in Chemical Formula B-1 may be linked to each other to form a ring, and two adjacent ones of Ar^{1a}Ar^{2a}, R^{1a} and R^{2a} may be, for example, linked by a single bond, —(CR^{g}R^{h})ₙ₁— (n1 is 1 or 2), —O—, —S—, —Se—, —N═, —NRⁱ—, —SiR^{j}R^{k}—, —GeR^{l}R^{m}—, and a divalent hydrocarbon group to form a ring. Herein R^{g} to R^{m} may each independently be hydrogen, a substituted or unsubstituted C1 to C30 alkyl group, a substituted or unsubstituted C6 to C30 aryl group, a substituted or unsubstituted C3 to C30 heteroaryl group, a substituted or unsubstituted C1 to C30 alkoxy group, a halogen, or a cyano group.

As an example, the p-type semiconductor may be represented by Chemical Formula B-1a or B-1b.

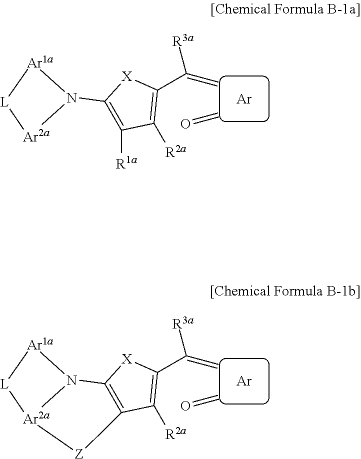

In Chemical Formulas B-1a and B-1b,
X, Ar, Ar^{1a}, Ar^{2a}, and R^{1a} to R^{3a} may be the same as X, Ar, Ar^{1a}, Ar^{2a}, and R^{1a} to R^{3a} as described above with reference to Chemical Formula B-1, respectively, and
L and Z may each independently be a single bond, O, S, Se, Te, SO, SO₂, —(CR^{g}R^{h})ₙ₁— (n1 is 1 or 2), —N═, —NRⁱ—, —SiR^{j}R^{k}—, and —GeR^{l}R^{m}—, a substituted or unsubstituted C1 to C30 alkylene group, a substituted or unsubstituted C3 to C30 cycloalkylene group, a substituted or unsubstituted C6 to C30 arylene group, or any combination thereof, where R^{g} to R^{m} may each independently be hydrogen, a substituted or unsubstituted C1 to C30 alkyl group, a substituted or unsubstituted C6 to C30 aryl group, a substituted or unsubstituted C3 to C30 heteroaryl group, a substituted or unsubstituted C1 to C30 alkoxy group, a halogen, or a cyano group.

As an example, the n-type semiconductor may be fullerene or a fullerene derivative. Examples of the fullerene may include C60, C70, C76, C78, C80, C82, C84, C90, C96, C240, C540, a mixture thereof, a fullerene nanotube, and the like. The fullerene derivative may refer to compounds of these fullerenes having a substituent thereof. The fullerene derivative may include a substituent such as an alkyl group (e.g., C1 to C30 alkyl group), an aryl group (e.g., C6 to C30 aryl group), a heterocyclic group (e.g., C3 to C30 heterocycloalkyl group), and the like. Examples of the aryl groups and heterocyclic groups may be a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, a isobenzofuran ring, a benzimidazole ring, a imidazopyridine ring, a quinolizidine ring, a quinoline ring, a phthalazine ring, a naphthyridine ring, a quinoxaline ring, an isoquinoline ring, a carbazole ring, a phenanthridine ring, an acridine ring, a phenanthroline ring, a thianthrene ring, a chromene ring, an xanthene ring, a phenoxazine ring, a phenoxathiin ring, a phenothiazine ring, or a phenazine ring.

For example, the n-type semiconductor may be a transparent material that does not absorb light in the visible wavelength spectrum (e.g., is configured to not absorb any light in the visible wavelength spectrum), for example, a transparent organic material. The transparent material (or transparent organic material) may have a wide energy bandgap such that it does not substantially absorb light in the visible wavelength spectrum, and it may have, for example, an energy bandgap of greater than or equal to about 2.5 eV, within this range, for example, an energy bandgap of about 2.5 eV to about 6.0 eV.

The photoelectric conversion layer 30 may include an intrinsic layer (I layer) in which a p-type semiconductor and an n-type semiconductor are mixed in a bulk heterojunction form. Herein, the p-type semiconductor and the n-type semiconductor may be mixed in a volume ratio of about 1:9 to about 9:1, and may be mixed within the range, for example, in a volume ratio of about 2:8 to about 8:2, in a volume ratio of about 3:7 to about 7:3, in a volume ratio of about 4:6 to about 6:4, or in a volume ratio of about 5:5.

The photoelectric conversion layer 30 may include a bilayer including a p-type layer including the aforementioned p-type semiconductor and an n-type layer including the aforementioned n-type semiconductor. Herein, a thickness ratio of the p-type layer and the n-type layer may be about 1:9 to about 9:1, for example about 2:8 to about 8:2, about 3:7 to about 7:3, about 4:6 to about 6:4, or about 5:5.

The photoelectric conversion layer 30 may include an intrinsic layer (I layer), a p-type layer, and/or an n-type layer. For example, the photoelectric conversion layer 30 may be included in various combinations such as p-type layer/I layer, I layer/n-type layer, and p-type layer/I layer/n-type layer.

A thickness of the photoelectric conversion layer 30 may be about 5 nm to about 1 μm, and within the above range, about 5 nm to about 800 nm, about 10 nm to about 600 nm, or about 10 nm to about 300 nm.

The first organic auxiliary layer 35 is between the anode 10 and the photoelectric conversion layer 30. The first organic auxiliary layer 35 may be in contact (e.g., direct contact) with one surface (for example, the upper surface or the lower surface) of the photoelectric conversion layer 30 and may be between the anode 10 and the photoelectric conversion layer 30. For example, in some example embodiments, one surface (e.g., an upper surface) of the first organic auxiliary layer 35 may be in contact with the photoconversion layer 30 and another surface (e.g., a lower surface) of the first auxiliary layer 35 may be in contact (e.g., direct contact) with the anode 10.

The first organic auxiliary layer 35 may include a singlet fission material (also referred to herein interchangeably as a first singlet fission material). The singlet fission material may be an organic light absorbing material configured to exhibit a phenomenon that the exciton in the singlet state (hereinafter referred to as “singlet exciton”) generated by absorbing one photon is divided into two excitons in the triplet state (hereinafter referred to as “triplet exciton”).

The singlet fission material included in the first organic auxiliary layer 35 may be represented by Chemical Formula 1, and may satisfy Relation Formula 1:

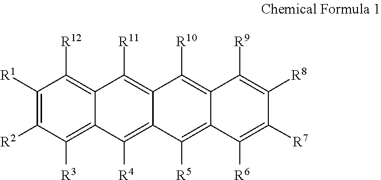

wherein, in the Chemical Formula 1,
R¹ to R¹² may each independently be hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heteroaryl group, a substituted or unsubstituted silyl group, a substituted or unsubstituted amine group, a halogen, a cyano group, or any combination thereof, provided that at least one of R¹ to R¹² is represented by Chemical Formula 2.

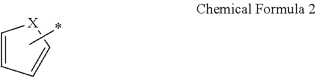

wherein, in the Chemical Formula 2,
X may be oxygen (O), sulfur (S), or tellurium (Te), for example, S or Se, or for example, S, and
* is a linking point with Chemical Formula 1.

$$E ( {S}_{1} ) + 0.5 eV \geq 2 \times E ( {T}_{1} ) \qquad Relation Formula 1$$

In Relation Formula 1,
E(S₁) is an excitation energy in a lowest singlet excited state of the singlet fission material, and
E(T₁) is the excitation energy in a lowest triplet excited state of the singlet fission material.

In Relation Formula 1, E(S₁) may be an energy required to be excited from a ground state (S₀) to the lowest single excited state (S₁), and E(T₁) may be an energy required to be excited from the ground state (S₀) to the lowest triplet excited state (T₁).

For example, E(S₁) may be an excitation energy in a lowest singlet excited state of the singlet fission material, and E(T₁) may be an excitation energy in a lowest triplet excited state of the singlet fission material. E(S₁) and E(T₁) may be calculation values of density functional theory (DFT), for example DFT calculation values, and specifically, calculation values obtained from DGDZVP basis sets under B3LYP functional conditions.

A singlet fission material satisfying Relation Formula 1 may be configured to absorb light which splits from the excited singlet state (S₁) to the triplet state (T₁) and generates amplified (e.g., approximately double) excitons, and these amplified excitons may be combined with the excitons generated from the photoelectric conversion layer 30 to increase an amount of carrier charges and thus increase efficiency of the sensor 100, wherein theoretically greater than about 100% of external quantum efficiency (EQE) and internal quantum efficiency (IQE) may be realized.

The singlet fission material may be different respectively from the p-type semiconductor and the n-type semiconductor of the photoelectric conversion layer 30. For example, the p-type semiconductor and the n-type semiconductor of the photoelectric conversion layer 30 respectively may not satisfy Relation Formula 1 (e.g., may not satisfy an energy level of the Relation Formula 1).

The singlet fission material may be configured to absorb light of at least one spectrum of a red wavelength spectrum, a green wavelength spectrum, a blue wavelength spectrum, or an infrared wavelength spectrum. For example, the singlet fission material may have an overlapped absorption spectrum with that of the p-type semiconductor and/or the n-type semiconductor of the photoelectric conversion layer 30. For example, in example embodiments where the p-type semiconductor and/or the n-type semiconductor is a material configured to selectively absorb light of a first wavelength spectrum selected from a red wavelength spectrum, a green wavelength spectrum, a blue wavelength spectrum, and an infrared wavelength spectrum, the singlet fission material may be a light-absorbing material configured to absorb light of the first wavelength spectrum. For example, in some example embodiments, the singlet fission material may be configured to selectively absorb light of a wavelength spectrum similar to a wavelength spectrum selectively absorbed by the p-type semiconductor and/or the n-type semiconductor. Accordingly, the sensor 100 may implement the enhanced electrical characteristics in a relatively narrow wavelength region (e.g., a narrow full width half maximum FWHM) belonging to the common wavelength region of the photoelectric conversion layer 30 and the first organic auxiliary layer 35.

The first wavelength spectrum may be, for example, a green wavelength spectrum, but is not limited thereto.

The singlet fission material may have an energy level at which the electrons generated from the amplified excitons described above and the excitons generated from the photoelectric conversion layer 30 are easily able to move toward the anode 10.

For example, the singlet fission material included in the first organic auxiliary layer 35 may have an equal or shallow HOMO energy level, compared with that of the p-type semiconductor included in the photoelectric conversion layer 30. For example, the HOMO energy level of the singlet fission material included in the first organic auxiliary layer 35 may be equal to or shallower than the HOMO energy level of the p-type semiconductor included in the photoelectric conversion layer 30. For example, the HOMO energy level of the singlet fission material included in the first organic auxiliary layer 35 may be between the HOMO energy level of the p-type semiconductor included in the photoelectric conversion layer 30 and a work function of the anode 10. In other words, the HOMO energy level of the p-type semiconductor included in the photoelectric conversion layer 30, the HOMO energy level of the singlet fission material included in the first organic auxiliary layer 35, and the work function of the anode 10 may have cascading energy levels.

For example, the HOMO energy level of the p-type semiconductor included in the photoelectric conversion layer 30 and the HOMO energy level of the singlet fission material included in the first organic auxiliary layer 35 may have a difference (absolute value reference) of greater than or equal to about 0 eV and less than about 1.0 eV and within the range, about 0 eV to about 0.8 eV, about 0 eV to about 0.7 eV, about 0 eV to about 0.5 eV, about 0 eV to about 0.3 eV, or about 0 eV to about 0.2 eV.

The singlet fission material included in the first organic auxiliary layer 35 may be represented by Chemical Formula 1. In the Chemical Formula 1, for example, at least one of R³ to R⁶ and at least one of R⁹ to R¹² may, each independently, be represented by Chemical Formula 2. For example, at least one of R⁴ and/or R⁵ and at least one of R¹⁰ and/or R¹¹ may, each independently, be represented by Chemical Formula 2. For example, both of R⁴ and R⁵ and both of R¹⁰ and R¹¹ may be represented by Chemical Formula 2. Or, for example, one of R⁴ and/or R⁵ may be represented by Chemical Formula 2, the other may be a substituted or unsubstituted C6 to C30 aryl group, for example, a substituted or unsubstituted phenyl group, or for example, unsubstituted phenyl group, and, one of R¹⁰ and/or R¹¹ may be represented by Chemical Formula 2, the other may be a substituted or unsubstituted C6 to C30 aryl group, for example, a substituted or unsubstituted phenyl group, or for example, unsubstituted phenyl group. Or, for example, one of R⁴ and/or R⁵ may be represented by Chemical Formula 2, the other may be hydrogen, and, one of R¹⁰ and R¹¹ may be represented by Chemical Formula 2, the other may be hydrogen. Or, for example, one of R⁴ and/or R⁵ and one of R¹⁰ and/or R¹¹ may be represented by Chemical Formula 2, in which the two represented by Chemical Formula 2 are in a position of point symmetry (e.g., rotational symmetry) with each other, and the others of R⁴ and/or R⁵ and R¹⁰ and/or R¹¹ may be hydrogens.

Alternatively, in Chemical Formula 1, for example, at least one of R¹ and/or R² and at least one of R⁷ and/or R⁸ may, each independently, be represented by Chemical Formula 2. For example, one of R¹ and/or R² and one of R⁷ and/or R⁸ may be represented by Chemical Formula 2. Or, for example, one of R¹ and/or R² may be represented by Chemical Formula 2, and the other may be hydrogen, deuterium, substituted or unsubstituted C6 to C30 aryl group, for example, a substituted or unsubstituted phenyl group, or for example, unsubstituted phenyl group, and, one of R⁷ and/or R⁸ may be represented by Chemical Formula 2, the other may be hydrogen, deuterium, a substituted or unsubstituted C6 to C30 aryl group, for example, a substituted or unsubstituted phenyl group, or for example, unsubstituted phenyl group, in which all of R³ to R⁶ and R⁹ to R¹² may, each independently, be hydrogen, deuterium, a substituted or unsubstituted C6 to C30 aryl group, for example, a substituted or unsubstituted phenyl group, or for example, unsubstituted phenyl group.

For example, in Chemical Formula 1, at least one of R¹ to R¹² may be represented by Chemical Formula 2, and the others may, each independently, be hydrogen or deuterium.

In Chemical Formula 1, when at least two of R¹ to R¹² are represented by Chemical Formula 2, the at least two may be in a symmetrical position, for example, in a point symmetry, a line symmetry, or a plane symmetry, with each other. It is thought that the singlet fission properties of the compound represented by Chemical Formula 1 may be better expressed when the group represented by Chemical Formula 2 is present at at least two positions that are symmetrical to each other, for example, two positions that are point-symmetrical to each other. Without intending to be bound by a particular theory, it is thought that when at least two groups represented by Chemical Formula 2 are present at positions that are symmetrical to each other, for example, at least two positions that are point-symmetrical to each other, the compound represented by Chemical Formula 1 may exist in a more stable form without causing steric hindrance.

For example, if one of R⁴ and/or R⁵ in Chemical Formula 1 is a group represented by Chemical Formula 2, for example, a thiophenyl group, that is, X is sulfur in Chemical Formula 2, one of R¹⁰ and/or R¹¹ at a position symmetrical to the position where the thiophenyl group exists among R⁴ and R⁵ may be a group represented by Chemical Formula 2, for example, a thiophenyl group, and all remaining positions other than the position where the thiophenyl group exists (e.g., the other of R⁴ and/or R⁵, the other of R¹⁰ and/or R¹¹, R¹ through R³, R⁶ through R⁹, and R¹²) may each be hydrogen.

For example, two or more groups represented by Chemical Formula 2 that are substituted in the compound represented by Chemical Formula 1 may be the same group. That is, in two or more groups represented by Chemical Formula 2, X may be the same. For example, in two or more groups represented by Chemical Formulas 2, X may all be sulfur, all be oxygen, or all be selenium, or for example, X may all be sulfur, but is not limited thereto. For example, in some example embodiments, two or more groups represented by Chemical Formula 2 present at positions that are symmetrical to each other may each include X that is the same. For example, two or more groups represented by Chemical Formula 2 present at positions that are symmetrical to each other may both include sulfur, oxygen, or selenium.

Alternatively, X of two or more groups represented by Chemical Formula 2 substituted in the compound represented by Chemical Formula 1 may be different from each other. For example, in two or more groups represented by Chemical Formula 2, one X may be sulfur and another X may be oxygen, or one X may be sulfur and another X may be selenium. For example, when substituted with four or more groups represented by Chemical Formulas 2, X in two groups may both be sulfur, and X of the other two groups may be oxygen or selenium, or, for example, X of the four groups may be two or more selected from oxygen, sulfur, or selenium. For example, in some example embodiments, two or more groups represented by Chemical Formula 2 present at positions that are symmetrical to each other may each include X that is different from each other. For example, where two or more groups represented by Chemical Formula 2 present at positions that are symmetrical to each other, a first group of the two or more groups represented by Chemical Formula 2 present at positions that are symmetrical to each other may include X that is sulfur, oxygen, or selenium, and a second group of the two or more groups represented by Chemical Formula 2 present at positions that are symmetrical to each other may include X that is sulfur, oxygen, or selenium different from the first group of the two or more groups represented by Chemical Formula 2 present at positions that are symmetrical to each other.

For example, the singlet fission material represented by Chemical Formula 1 may include any one described in Group 1 below, but is not limited thereto.

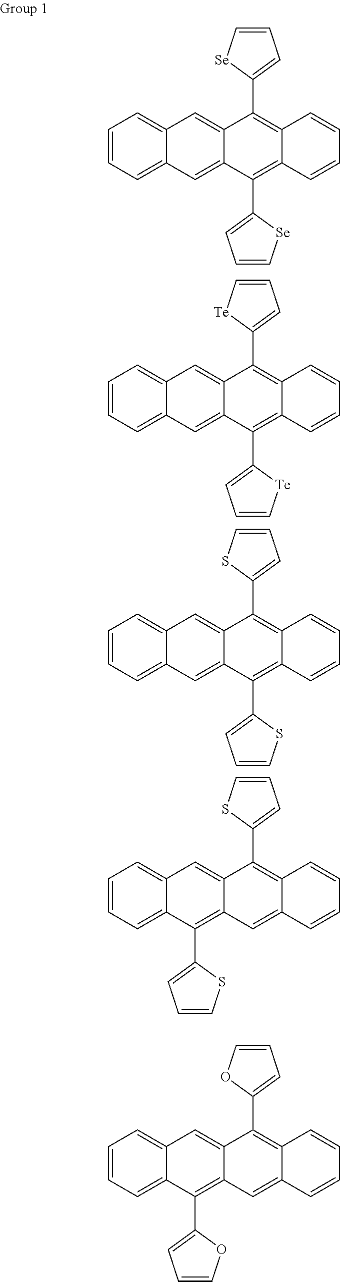

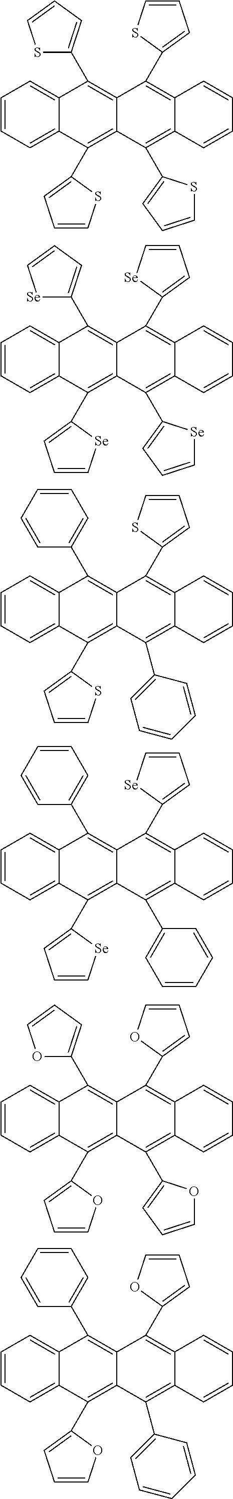

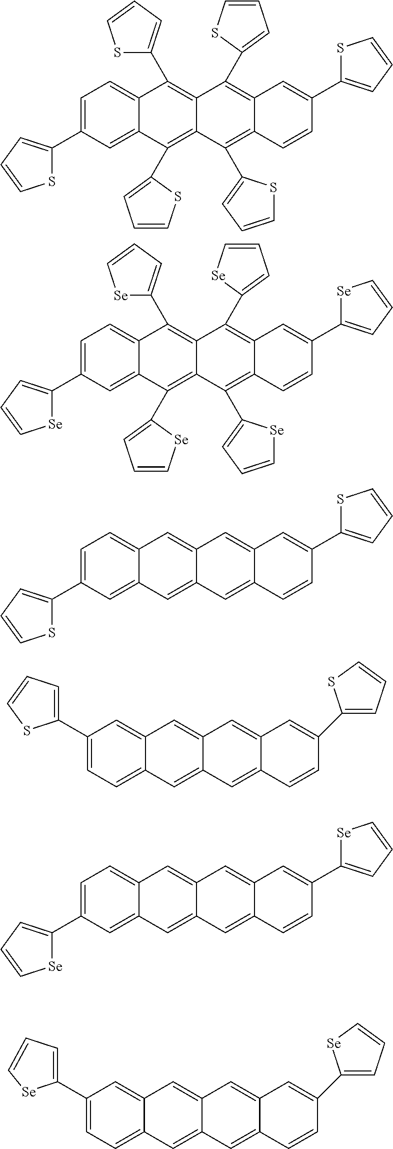

The singlet fission material represented by Chemical Formula 1 may be an organic light-absorbing material, and may be a wavelength-selective light-absorbing material that selectively absorbs light in various wavelength ranges depending on, for example, the structure of Chemical Formula 1, for example, the type and number of substituents substituted on each of R1 to R12, the number and substitution positions of the group represented by Chemical Formula 2, and the type of X element in Chemical Formula 2.

Singlet fission is a type of exciton multiplication and recognized as a representative method for overcoming the theoretical efficiency limit (Shockley-Quisser limit) of solar cells, and has been actively researched. However, many existing singlet fission materials are unstable in solution or thin film form, making them difficult to apply in practical processes. For example, rubrene possesses high hole-transport capacity and a long exciton diffusion length, making it a promising photovoltaic material, and is known to undergo effective singlet fission. However, rubrene is easily oxidized and unstable in air, requiring improvements in molecular stability for practical commercialization.

The singlet fission material represented by Chemical Formula 1 included in the first organic auxiliary layer 35 of the sensor 100 according to some example embodiments includes one or more pentagonal heterocycles represented by Chemical Formula 2 substituted to the tetracene core of the material, and the compound represented by Chemical Formula 1, which is a tetracene derivative substituted with the pentagonal heterocycle, may not only maintain a high singlet fission effect in terms of speed and yield, but also have high stability both in solution and in a thin film, for example, improved chemical durability and phase stability. Therefore, the singlet fission material represented by Chemical Formula 1 may be easily manufactured into a thin film by a deposition or solution process known in the art, and the manufactured thin film may be maintained stably in the air for a long period of time by itself or sealed with a sealant. Accordingly, a sensor 100 including a first organic auxiliary layer 35 manufactured in the form of a thin film by depositing or solution-processing a singlet fission material represented by Chemical Formula 1 on an anode 10 may implement high sensitivity and stable electrical characteristics.

Table 1 below shows the results of calculating the energy levels of compounds in which the group represented by Chemical Formula 2 is introduced at various positions of R¹ to R¹² of the compound represented by Chemical Formula 1.

TABLE 1

| | | | | S₁ | | | | 2* |
|---|---|---|---|---|---|---|---|---|
| | HOMO | LUMO | Dipole | vert | Uncor- | T₁ | S₁ | T₁-S₁ |
| Compound | (eV) | (eV) | Moment | Osc. | rected | (vert.) | (vert.) | (vert.) |
| 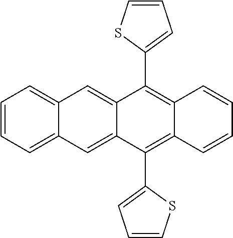 [SMILES: c1csc(-c2c3ccccc3c(-c3cccs3)c3cc4ccccc4cc23)c1] | −5.18 | −2.54 | 0.09 | 0.19 | 481.55 | 1.37 | 2.57 | 0.17 |
| 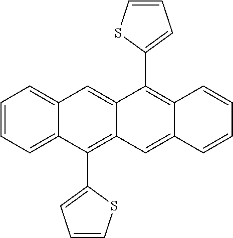 [SMILES: c1csc(-c2c3ccccc3cc3c(-c4cccs4)c4ccccc4cc23)c1] | −5.19 | −2.54 | 0.00 | 0.19 | 480.15 | 1.38 | 2.58 | 0.18 |
| 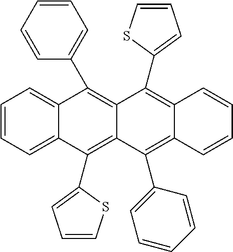 [SMILES: c1ccc(-c2c3ccccc3c(-c3cccs3)c3c(-c4ccccc4)c4ccccc4c(-c4cccs4)c23)cc1] | −5.01 | −2.56 | 0.95 | 0.27 | 527.79 | 1.23 | 2.35 | 0.10 |
| 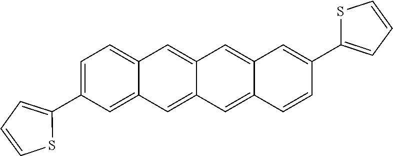 [SMILES: c1csc(-c2ccc3cc4cc5cc(-c6cccs6)ccc5cc4cc3c2)c1] | −5.11 | −2.56 | 0.00 | 0.17 | 484.38 | 1.41 | 2.56 | 0.27 |
| 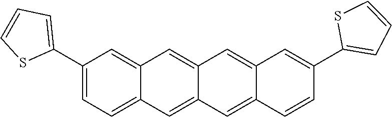 [SMILES: c1csc(-c2ccc3cc4cc5ccc(-c6cccs6)cc5cc4cc3c2)c1] | −5.13 | −2.55 | 0.82 | 0.04 | 480.53 | 1.42 | 2.58 | 0.25 |
| 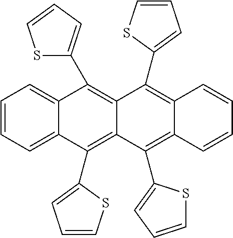 [SMILES: c1csc(-c2c3ccccc3c(-c3cccs3)c3c(-c4cccs4)c4ccccc4c(-c4cccs4)c23)c1] | −5.10 | −2.69 | 0.00 | 0.19 | 537.59 | 1.20 | 2.31 | 0.08 |
| 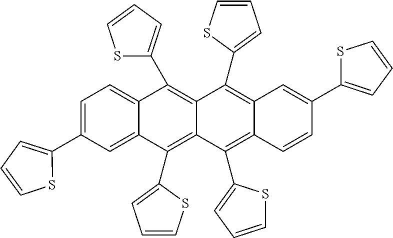 [SMILES: c1csc(-c2ccc3c(-c4cccs4)c4c(-c5cccs5)c5cc(-c6cccs6)ccc5c(-c5cccs5)c4c(-c4cccs4)c3c2)c1] | −5.10 | −2.53 | 1.07 | 0.21 | 494.2 | 1.34 | 2.51 | 0.17 |
| 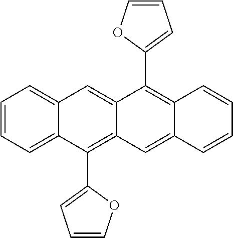 [SMILES: c1coc(-c2c3ccccc3cc3c(-c4ccco4)c4ccccc4cc23)c1] | −5.05 | −2.77 | 0.60 | 0.26 | 558.17 | 1.17 | 2.22 | 0.13 |
| 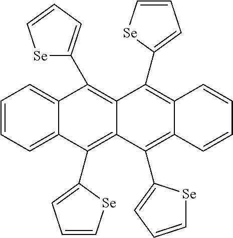 [SMILES: c1c[se]c(-c2c3ccccc3c(-c3ccc[se]3)c3c(-c4ccc[se]4)c4ccccc4c(-c4ccc[se]4)c23)c1] | −5.05 | −2.71 | 0.71 | 0.31 | 555.73 | 1.15 | 2.23 | 0.06 |

From Table 1, it can be seen that the compound represented by Chemical Formula 1 is a singlet fission material that satisfies the above Relation Formula 1.

Meanwhile, the singlet fission material represented by Chemical Formula 1 may be a light-absorbing material that selectively absorbs light of a first wavelength spectrum selected from a red wavelength spectrum, a green wavelength spectrum, a blue wavelength spectrum, and/or an infrared wavelength spectrum. Therefore, the sensor 100 including the first organic auxiliary layer 35 that includes the compound represented by Chemical Formula 1, which satisfies Relation Formula 1 and the energy levels described above, may generate an amplified (e.g., approximately double) exciton, while also having good hole transfer characteristics, and may thereby implement improved external quantum efficiency (EQE) and internal quantum efficiency (IQE) in a relatively narrow wavelength region (e.g., narrow FWHM). Thus, a high-sensitivity sensor 100 may be obtained. Accordingly, the sensor 100 may implement more enhanced electrical characteristics for light of the first wavelength spectrum, and the first wavelength spectrum may be, for example, a wavelength (λₘₐₓ,EQE) that represents the maximum external quantum efficiency of the sensor and a wavelength (λₘₐₓ,IQE) that represents the maximum internal quantum efficiency. For example, the first wavelength spectrum may be, but is not limited to, a green wavelength spectrum.

The thickness of the first organic auxiliary layer 35 may be the same as or thinner than the thickness of the photoelectric conversion layer 30, and may be, for example, about 1 nm to about 500 nm, and within the above range, about 2 nm to about 300 nm, about 5 nm to about 200 nm, about 5 nm to about 100 nm, about 10 nm to about 80 nm, or about 10 nm to about 50 nm.

Hereinafter, another example of a sensor according to some example embodiments will be described.

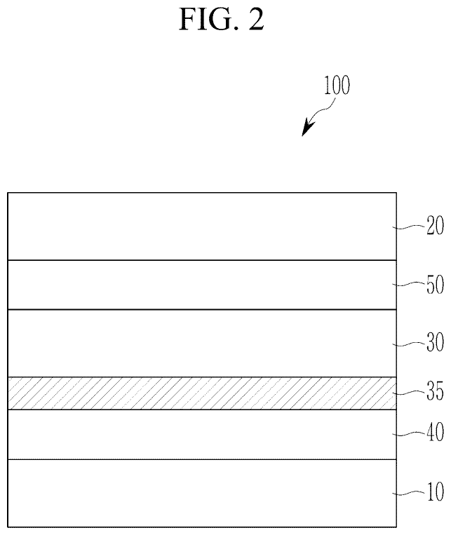

FIG. 2 is a cross-sectional view showing an example of a sensor according to some example embodiments.

Referring to FIG. 2, the sensor 100 according to some example embodiments, like the aforementioned example embodiments shown in FIG. 1, includes an anode 10, a cathode 20, a photoelectric conversion layer 30, and a first organic auxiliary layer 35. Descriptions of the anode 10, the cathode 20, the photoelectric conversion layer 30, and the first organic auxiliary layer 35 are as described above with reference to FIG. 1.

However, unlike some example embodiments, including the aforementioned example embodiments shown in FIG. 1, the sensor 100 according to some example embodiments, including the example embodiments shown in FIG. 2, further includes hole auxiliary layer 40 and electron auxiliary layer 50.

The hole auxiliary layer 40 may be between the anode 10 and the first organic auxiliary layer 35, for example, one surface of the hole auxiliary layer 40 may be in contact (e.g., direct contact) with the anode 10, and the other surface (e.g., opposite surface) of the hole auxiliary layer 40 may be in contact (e.g., direct contact) with the first organic auxiliary layer 35.

The hole auxiliary layer 40 may effectively increase the extraction of holes moving from the photoelectric conversion layer 30 to the anode 10 through the first organic auxiliary layer 35 and/or may effectively reduce, minimize, or prevent reverse movement of holes from the photoelectric conversion layer 30 to the anode 10 through the first organic auxiliary layer 35, thereby improving the image sensing performance and/or efficiency (e.g., sensitivity) of the sensor 100.

For example, the LUMO energy level of the hole auxiliary layer 40 may be shallower than each of the work function of the anode 10 and the LUMO energy level of the p-type semiconductor of the photoelectric conversion layer 30. For example, the LUMO energy level of the hole auxiliary layer 40 may be shallower than each of the work function of the anode 10 and the LUMO energy level of the n-type semiconductor of the photoelectric conversion layer 30 in the range of about 0 to about 2.5 eV, about 0.1 eV to about 2.5 eV, about 0.2 eV to about 2.2 eV, about 0.4 eV to about 2.0 eV, or about 0.5 eV to about 1.8 eV. Accordingly, it is possible to effectively block or reduce the reverse movement of electrons from the photoelectric conversion layer 30 to the anode 10 through the first organic auxiliary layer 35.

The hole auxiliary layer 40 may include, for example, organic materials, inorganic materials, and/or organic and inorganic materials. The hole auxiliary layer 40 may be made of a phthalocyanine compound such as copper phthalocyanine; an aromatic amine compound such as DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′4″-tris(N,N-diphenylamino)triphenylamine), or 2-TNATA (4,4′,4″-tris{N,-(2-naphthyl)-N-phenylamino}-triphenylamine); PEDOT/PSS (poly(3,4-ethylenedioxythiophene)/poly(4-styrenesulfonate)); PANI/DBSA (polyaniline/dodecylbenzenesulfonic acid); PANI/CSA (polyaniline/Camphor sulfonic acid); PANI/PSS (polyaniline/poly(4-styrenesulfonate)); NPB(N,N′-di(naphthalene-I-yl)-N,N′-diphenylbenzidine); polyetherketone (TPAPEK) containing triphenylamine; 4-isopropyl-4′-methyldiphenyliodonium[tetrakis(pentafluorophenyl)borate]; HAT-CN (dipyrazino[2,3-f: 2′,3′-h]quinoxaline-2,3,6,7,10,11-hexacarbonitrile); a carbazole-based derivative such as N-phenylcarbazole or polyvinylcarbazole; a fluorine-based derivative; a triphenylamine-based derivative such as TPD (N,N′-bis(3-methylphenyl)-N,N′-diphenyl-[1,1-biphenyl]-4,4′-diamine) or TCTA (4,4′,4″-tris(N-carbazolyl)triphenylamine); TAPC (4,4′-cyclohexylidene bis[N,N-bis(4-methylphenyl)benzenamine]); HMTPD (4,4′-bis[N,N′-(3-tolyl)amino]-3,3′-dimethylbiphenyl); mCP (1,3-bis(N-carbazolyl)benzene); HT211 (N-[1,1′-Diphenyl]-4-yl-9,9-dimethyl-N-[4-(9-phenyl-9H-carbazol-3-yl)phenyl]-9H-fluorene-2-amine); or any combination thereof, but is not limited thereto.

The electron auxiliary layer 50 may be between the cathode 20 and the photoelectric conversion layer 30, and for example, one surface of the electron auxiliary layer 50 may be in contact (e.g., direct contact) with the cathode 20, and the other surface (e.g., opposite surface) of the electron auxiliary layer 50 may be in contact (e.g., direct contact) with the photoelectric conversion layer 30. The electron auxiliary layer 50 may effectively increase the extraction of electrons moving from the photoelectric conversion layer 30 to the cathode 20 or may effectively reduce, minimize, or prevent reverse movement of holes from the photoelectric conversion layer 30 to the cathode 20, thereby improving the image sensing performance and/or efficiency (e.g., sensitivity) of the sensor 100.

The electron auxiliary layer 50 may include, for example, organic materials, inorganic materials, and/or both organic and inorganic materials. The electron auxiliary layer 50 may be made of a metal halide, such as, for example, LiF, NaCl, CsF, RbCl, and RbI; a metal oxide such as Li₂O and BaO; Liq (lithium quinolate), Alq₃ (tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tri(1-phenyl-1H-benzo[d]imidazol-2-yl)phenyl), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tertbutylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), Bebq2 (berylliumbis(benzoquinolin-10-olate), AND (9,10-di(naphthalene-2-yl)anthracene), BmPyPhB (1,3-bis[3,5-di(pyridin-3-yl)phenyl]benzene), or any combination thereof, but is not limited thereto.

The hole auxiliary layer 40 and the electron auxiliary layer 50 may each have one or more layers. One or more of the hole auxiliary layer 40 or the electron auxiliary layer 50 may be omitted.

Hereinafter, another example of a sensor according to some example embodiments will be described.

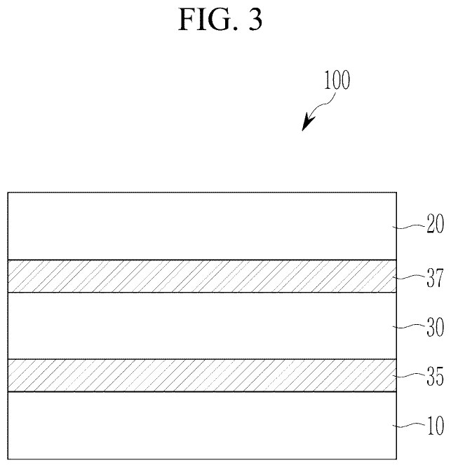

FIG. 3 is a cross-sectional view showing a sensor according to some example embodiments.

Referring to FIG. 3, the sensor 100 according to some example embodiments includes an anode 10, a cathode 20, a photoelectric conversion layer 30, and a first organic auxiliary layer 35, as described above. The description of the anode 10, the cathode 20, the photoelectric conversion layer 30, and the first organic auxiliary layer 35 is the same as described above.

However, unlike some example embodiments, including the example embodiments shown in FIGS. 1 and 2, the sensor 100 according to some example embodiments, including the example embodiments shown in FIG. 3, further includes a second organic auxiliary layer 37.

The second organic auxiliary layer 37 may be between the cathode 20 and the photoelectric conversion layer 30, for example, one surface (e.g., the lower surface) of the second organic auxiliary layer 37 may be in contact (e.g., direct contact) with the photoelectric conversion layer 30. That is, the first organic auxiliary layer 35, the photoelectric conversion layer 30, and the second organic auxiliary layer 37 may be sequentially stacked in contact (e.g., direct contact) with each other (e.g., such that the photoelectric conversion layer is directly between the first organic auxiliary layer and the second organic auxiliary layer 37).

The second organic auxiliary layer 37 may include a singlet fission material, and the singlet fission material may be an organic absorbing material exhibiting a phenomenon in which a singlet exciton generated by absorbing one photon is divided into two triplet excitons, and may be an organic absorbing material satisfying the above-described Relation Formula 1.

The singlet fission material included in the second organic auxiliary layer 37 may be different from the singlet fission material included in the first organic auxiliary layer 35, and may be different from the p-type semiconductor and the n-type semiconductor included in the photoelectric conversion layer 30.

The singlet fission material in the second organic auxiliary layer 37 (also referred to herein interchangeably as a second singlet fission material) may be configured to absorb light of at least one spectrum of a red wavelength spectrum, a green wavelength spectrum, a blue wavelength spectrum, or an infrared wavelength spectrum. For example, the singlet fission material included in the second organic auxiliary layer 37 may have an overlapped absorption spectrum with that of the p-type semiconductor and/or the n-type semiconductor of the photoelectric conversion layer 30 and that of the singlet fission material (e.g., first singlet fission material) included in the first organic auxiliary layer 35. For example, in example embodiments where the p-type semiconductor and/or the n-type semiconductor, and the singlet fission material included in the first organic auxiliary layer 35 may be one or more materials configured to selectively absorb light of a first wavelength spectrum selected from a red wavelength spectrum, a green wavelength spectrum, a blue wavelength spectrum, and an infrared wavelength spectrum, the singlet fission material included in the second organic auxiliary layer 37 may be a light-absorbing material configured to absorb light of the first wavelength spectrum.

For example, the first wavelength spectrum may be a green wavelength spectrum, and accordingly, the p-type semiconductor and/or the n-type semiconductor, the singlet fission material included in the first organic auxiliary layer 35, and singlet fission material included in the second organic auxiliary layer 37 may each be an organic absorbing material configured to selectively absorb light in the green wavelength spectrum, and this common absorption wavelength spectrum may correspond to the sensing wavelength of the sensor 100.

For example, the singlet fission material included in the second organic auxiliary layer 37 may have an equal or deeper LUMO energy level, compared with that of the n-type semiconductor included in the photoelectric conversion layer 30. For example, the LUMO energy level of the singlet fission material included in the second organic auxiliary layer 37 may be between the LUMO energy level of the n-type semiconductor included in the photoelectric conversion layer 30 and a work function of the cathode 20. In other words, the LUMO energy level of the n-type semiconductor included in the photoelectric conversion layer 30, the LUMO energy level of the singlet fission material included in the second organic auxiliary layer 37, and the work function of the cathode 20 may have cascading energy levels. For example, the LUMO energy level of the n-type semiconductor included in the photoelectric conversion layer 30 and the LUMO energy level of the singlet fission material included in the second organic auxiliary layer 37 may have a difference (absolute value reference) of greater than or equal to about 0 eV and less than about 1.0 eV and within the range, about 0 eV to about 0.8 eV, about 0 eV to about 0.7 eV, about 0 eV to about 0.5 eV, about 0 eV to about 0.3 eV, or about 0 eV to about 0.2 eV.

The singlet fission material included in the second organic auxiliary layer 37 is not particularly limited as long as it is an organic material that satisfies the aforementioned Relation Formula 1 and energy levels thereof, and may be, for example, a monomer, dimer, or polymer. For example, the singlet fission material included in the second organic auxiliary layer 37 may be represented by Chemical Formula 3, and is not limited thereto.

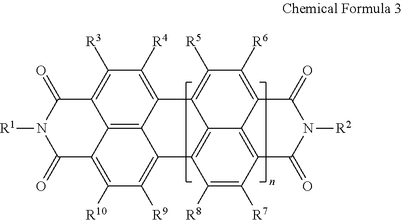

wherein in Chemical Formula 3,
R¹ to R¹⁰ may each independently be hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heteroaryl group, a substituted or unsubstituted silyl group, a substituted or unsubstituted amine group, a halogen, a cyano group, or any combination thereof,
R¹ to R¹⁰ may each be independently or two adjacent ones among R¹ to R¹⁰ may be linked to form a ring, and
n may be an integer from 0 to 3.

For example, R¹ to R¹⁰ may each independently be hydrogen, a substituted or unsubstituted methyl group, a substituted or unsubstituted ethyl group, a substituted or unsubstituted propyl group, a substituted or unsubstituted butyl group, a substituted or unsubstituted pentyl group, a substituted or unsubstituted hexyl group, a substituted or unsubstituted phenyl group, a substituted or unsubstituted biphenyl group, a substituted or unsubstituted naphthyl group, or any combination thereof.

For example, n may be 1.

For example, the singlet fission material included in the second organic auxiliary layer 37 may be an organic compound listed in Table 2 below, but is not limited thereto.

TABLE 2

| | HOMO (eV) | LUMO (eV) |
|---|---|---|
| 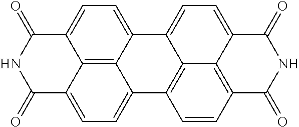 [SMILES: O=C1NC(=O)c2ccc3c4ccc5c6c(ccc(c7ccc1c2c73)c64)C(=O)NC5=O] | 6.38 | 4.44 |
| 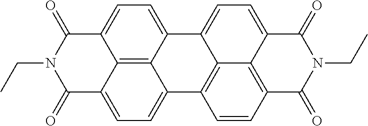 [SMILES: CCN1C(=O)c2ccc3c4ccc5c6c(ccc(c7ccc(c2c37)C1=O)c64)C(=O)N(CC)C5=O] | 6.44 | 4.19 |
| 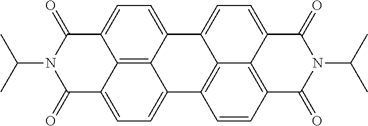 [SMILES: CC(C)N1C(=O)c2ccc3c4ccc5c6c(ccc(c7ccc(c2c37)C1=O)c64)C(=O)N(C(C)C)C5=O] | 6.37 | 4.28 |
| 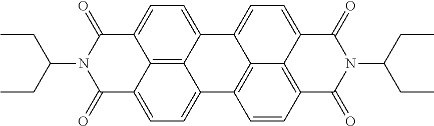 [SMILES: CCC(CC)N1C(=O)c2ccc3c4ccc5c6c(ccc(c7ccc(c2c37)C1=O)c64)C(=O)N(C(CC)CC)C5=O] | 6.50 | 4.37 |

The thicknesses of the second organic auxiliary layer 37 may be the same as or thinner than the thickness of the photoelectric conversion layer 30, and may be, for example, about 1 nm to about 500 nm, and within the above range, about 2 nm to about 300 nm, about 5 nm to about 200 nm, about 5 nm to about 100 nm, about 10 nm to about 80 nm, or about 10 nm to about 50 nm.

The sensor 100 according to some example embodiments, including the example embodiments shown in FIG. 3, may include the first and second organic auxiliary layers 35 and 37 on both sides (e.g., opposite sides) of the photoelectric conversion layer 30 to more effectively generate the amplified exciton, and at the same time, electron transfer characteristics and hole transfer characteristics are also good, thereby implementing a sensor 100 exhibiting improved external quantum efficiency (EQE) and internal quantum efficiency (IQE). In some example embodiments, the first organic auxiliary layer 35 may be in contact (e.g., direct contact) with a first (e.g., lower) surface of the photoelectric conversion layer 30 and the second organic auxiliary layer 37 may be in contact (e.g., direct contact) with a second (e.g., upper) surface of the photoelectric conversion layer 30 such that the photoelectric conversion layer is between (e.g., directly between) the first organic auxiliary layer 35 and the second organic auxiliary layer 37.

Hereinafter, another example of a sensor according to some example embodiments will be described.

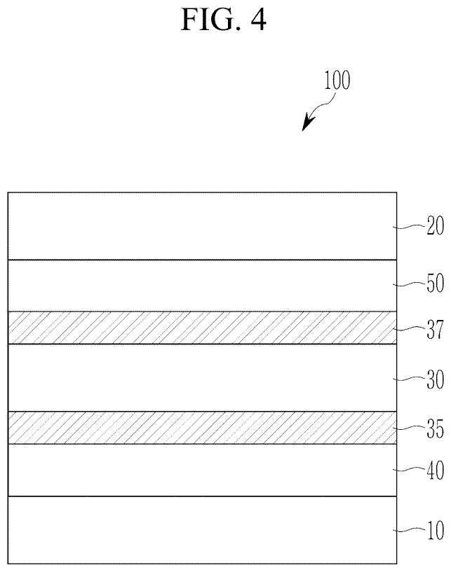

FIG. 4 is a cross-sectional view showing a sensor according to some example embodiments.

Referring to FIG. 4, the sensor 100 according to some example embodiments, like the aforementioned example embodiments shown in FIG. 3, includes an anode 10, a cathode 20, a photoelectric conversion layer 30, a first organic auxiliary layer 35, and a second organic auxiliary layer 37. Descriptions of the anode 10, the cathode 20, the photoelectric conversion layer 30, and the first and second organic auxiliary layers 35 and 37 are as described above referring to FIG. 3.

However, unlike some example embodiments, including the aforementioned example embodiments shown in FIG. 3, the sensor 100 according to some example embodiments, including the example embodiments shown in FIG. 4, further includes hole auxiliary layer 40 and electron auxiliary layer 50.

The hole auxiliary layer 40 may be between the anode 10 and the first organic auxiliary layer 35, for example, one surface of the electron auxiliary layer 40 may be in contact with the anode 10, and the other surface (e.g., opposite surface) of the hole auxiliary layer 40 may be in contact (e.g., direct contact) with the first organic auxiliary layer 35. The hole auxiliary layer 40 may effectively increase the extraction of holes moving from the photoelectric conversion layer 30 to the anode 10 through the first organic auxiliary layer 35 and/or may effectively reduce, minimize, or prevent reverse movement of electrons from the photoelectric conversion layer 30 to the anode 10 through the first organic auxiliary layer 35, thereby improving the image sensing performance and/or efficiency (e.g., sensitivity) of the sensor 100.

The electron auxiliary layer 50 may be between the cathode 20 and the second organic auxiliary layer 37, and for example, one surface of the electron auxiliary layer 50 may be in contact with the cathode 20, and the other surface (e.g., opposite surface) of the electron auxiliary layer 50 may be in contact (e.g., direct contact) with the second organic auxiliary layer 37. The electron auxiliary layer 50 may effectively increase the extraction of electrons moving from the photoelectric conversion layer 30 to the cathode 20 through the second organic auxiliary layer 37 or may effectively reduce, minimize, or prevent reverse movement of holes from the photoelectric conversion layer 30 to the cathode 20 through the second organic auxiliary layer 37, thereby improving the image sensing performance and/or efficiency (e.g., sensitivity) of the sensor 100.

For example, the HOMO energy level of the electron auxiliary layer 50 may be deeper than each of the work function of the cathode 20 and the HOMO energy level of the p-type semiconductor of the photoelectric conversion layer 30, and may be additionally deeper than the HOMO energy level of the singlet fission material of the second organic auxiliary layer 37. For example, the HOMO energy level of the electron auxiliary layer 50 may be deeper than each of the work function of the cathode 20 and the HOMO energy level of the p-type semiconductor of the photoelectric conversion layer 30 in the range of about 0 to about 3.5 eV, about 0.1 eV to about 3.3 eV, about 0.2 eV to about 3.2 eV, about 0.4 eV to about 3.0 eV, or about 0.5 eV to about 2.9 eV. Accordingly, it is possible to effectively block or reduce the reverse movement of holes from the photoelectric conversion layer 30 to the cathode 20 through the second organic auxiliary layer 37.

The hole auxiliary layer 40 and the electron auxiliary layer 50 may each have one or more layers. One or more of the hole auxiliary layer 40 or the electron auxiliary layer 50 may be omitted.

The aforementioned sensor 100 may be applied to, for example, an image sensor. As described above, the sensor 100 may exhibit high efficiency (e.g., improved photoelectric conversion performance and/or power consumption efficiency), and thus it may be effectively applied to image sensors used in low-illumination environments and/or image sensors that require high efficiency.

Hereinafter, an image sensor to which the aforementioned sensor 100 is applied will be described with reference to the drawings. Here, a CMOS image sensor will be described as an image sensor according to some example embodiments.

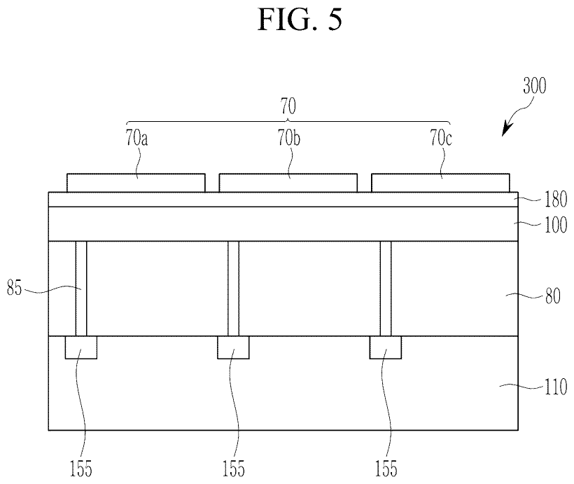

FIG. 5 is a cross-sectional view showing an image sensor according to some example embodiments.

Referring to FIG. 5, an example of the image sensor 300 according to some example embodiments includes a substrate 110, an insulation layer 80, a sensor 100, and a color filter layer 70.

The substrate 110 may be a semiconductor substrate, for example, a silicon substrate or a compound semiconductor substrate. A transmission transistor (not shown) and a charge storage 155 may be integrated for each pixel on the substrate 110, and each charge storage 155 is electrically connected to the sensor 100 of each pixel.

Metal wires (not shown) and pads (not shown) are formed on the front or rear side of the substrate 110. In order to decrease signal delay, the metal wire and pad may be made of a metal having low resistivity, for example, aluminum (AI), copper (Cu), silver (Ag), molybdenum (Mo), nickel (Ni), an alloy thereof, or any combination thereof, but the example embodiments are not limited thereto.

The insulation layer 80 is formed on the substrate 110. The insulation layer 80 may be made of an inorganic insulating material such as a silicon oxide and/or a silicon nitride, or a low dielectric constant (low K) material such as SiC, SiCOH, SiCO, and/or SiOF. The insulation layer 80 has a trench 85 exposing the charge storage 155. The trench 85 may be filled with fillers.

The aforementioned sensor 100 is formed on the insulation layer 80. The sensor 100 may have one of the structures shown in FIGS. 1 to 4, and the detailed description is as described above. One of the anode 10 or the cathode 20 of the sensor 100 may be a light-receiving electrode (or incident electrode) disposed on the side receiving light (e.g., the light incident side, which may be the side closest to the color filter layer 70), and the other of the anode 10 or the cathode 20 of the sensor 100 may be electrically connected to the charge storage 155. For example, the anode 10 of the sensor 100 may be a light-receiving electrode, and the cathode 20 of the sensor 100 may be electrically connected to the charge storage 155. For example, the cathode 20 of the sensor 100 may be a light-receiving electrode and the anode 10 of the sensor 100 may be electrically connected to the charge storage 155.

A color filter layer 70 is formed on the sensor 100. The color filter layer 70 may include a plurality of color filters configured to selectively transmit one or two of the red wavelength spectrum, the green wavelength spectrum, and/or the blue wavelength spectrum, and may include, for example, a first color filter 70a configured to selectively transmit light including a red wavelength spectrum, a second color filter 70b configured to selectively transmit light including a blue wavelength spectrum, and a third color filter 70c configured to selectively transmit light including a green wavelength spectrum. For example, the first color filter 70a may be a red filter, a magenta filter, and/or a yellow filter, for example, the second color filter 70b may be a blue filter, a cyan filter, and/or a magenta filter, and for example, the third color filter 70c may be a green filter, a cyan filter, and/or a yellow filter, and the first, second, and third color filters 70a, 70b, and 70c may be different from each other. The color filter layer 70 may be omitted.

A passivation film 180 is formed between the sensor 100 and the color filter layer 70. The passivation film 180 may be an oxide film, a nitride film, a double layer of an oxide film and a nitride film, or the like. The passivation film 180 may be omitted.

Focusing lens (not shown) may be further formed on the color filter layer 70. The focusing lens may control a direction of incident light and gather the light in one region. The focusing lens may have a shape of, for example, a cylinder or a hemisphere, but is not limited thereto.

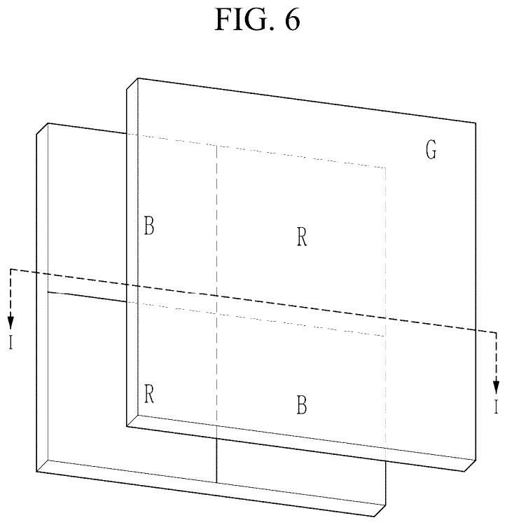

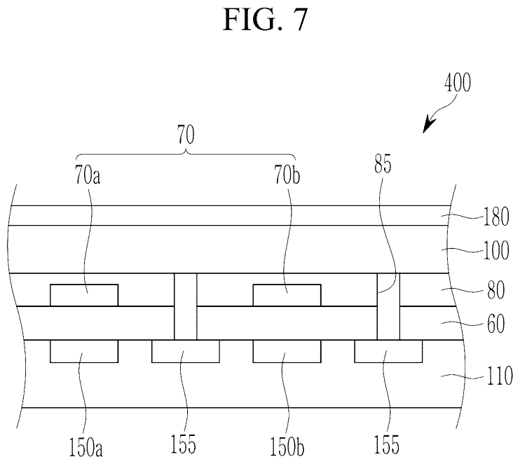

FIG. 6 is a plan view showing an image sensor according to some example embodiments, and FIG. 7 is a cross-sectional view taken along the I-I line of FIG. 6 according to some example embodiments.

Referring to FIGS. 6 and 7, an image sensor 400 according to some example embodiments includes a substrate 110 integrated with photo-sensing elements 150a and 150b, a transmission transistor (not shown), and a charge storage 155, a lower insulation layer 60, a color filter layer 70, an upper insulation layer 80, and the aforementioned sensor 100.

The substrate 110 may be, for example, a silicon substrate or a compound semiconductor substrate, and the photo-sensing elements 150a and 150b, the transmission transistor (not shown), and the charge storage 155 are integrated therein. The photo-sensing elements 150a and 150b may be photodiodes.

The photo-sensing elements 150a, and 150b, the transmission transistor, and/or the charge storage 155 may be integrated (e.g., included within a volume space defined by outermost surfaces of the substrate 110) for each pixel. The photo-sensing element 150a may be configured to sense the light passing through the sensor 100 and the first color filter 70a, and the photo-sensing element 150b may sense light that has passed through the sensor 100 and the second color filter 70b. The charge storage 155 may be electrically connected to the photo-sensing elements 150a and 150b or the sensor 100.

Metal wires (not shown) and pads (not shown) are formed on the front or back side of the substrate 110. In order to decrease signal delay, the metal wire and pad may be made of a metal having low resistivity, for example, aluminum (Al), copper (Cu), silver (Ag), molybdenum (Mo), nickel (Ni), an alloy thereof, or any combination thereof, but the example embodiments are not limited thereto. The lower insulation layer 60 is formed on the substrate 110. The lower insulation layer 60 may be made of an inorganic insulating material such as a silicon oxide and/or a silicon nitride, or a low dielectric constant (low K) material such as SiC, SiCOH, SiCO, and SiOF. The lower insulation layer 60 has (e.g., defines) a trench exposing the charge storage 155 (e.g., a lower portion of trench 85). The trench may be filled with fillers.

A color filter layer 70 is formed on the lower insulation layer 60. The color filter layer 70 includes a plurality of color filters 70a and 70b configured to selectively transmit light in the wavelength spectrum to be sensed by the photo-sensing elements 150a and 150b. The color filter 70a may be overlapped with the photo-sensing element 150a along the thickness direction of the substrate 110 (e.g., a direction extending perpendicular to an in-plane direction of the substrate 110), and the photo-sensing element 150a may sense light that has passed through the color filter 70a. The color filter 70b may be overlapped with the photo-sensing element 150b along the thickness direction of the substrate 110, and the photo-sensing element 150b may be configured to sense light that has passed through the color filter 70b.

The color filters 70a and 70b may be configured to selectively transmit one or two of the red wavelength spectrum, the green wavelength spectrum, or the blue wavelength spectrum. The wavelength spectrum selectively transmitted by the color filters 70a and 70b may be different from the aforementioned first wavelength spectrum selectively absorbed by the photoelectric conversion layer 30 of the sensor 100. For example, the first color filter 70a may be a red filter, a magenta filter, and/or a yellow filter, the second color filter 70b may be a blue filter, a cyan filter, and/or a magenta filter, and the first and second color filters 70a and 70b may be different from each other.

The upper insulation layer 80 is formed on the color filter layer 70. The upper insulation layer 80 may remove a step difference caused by the color filter layer 70 and planarize it. The upper insulation layer 80 and the lower insulation layer 60 have a contact (not shown) exposing the pad and a trench 85 exposing the charge storage 155.

The aforementioned sensor 100 is formed on the upper insulation layer 80. The sensor 100 may have one of the structures shown in FIGS. 1 to 4, and the detailed description is as described above.

One of the anode 10 or the cathode 20 of the sensor 100 may be a light-receiving electrode disposed on the side that receives (e.g., an upper surface as depicted in FIG. 7, an upper surface opposite a lower surface contacting upper insulation layer 80) the light (e.g., incident light), and the other of the anode 10 or the cathode 20 of the sensor 100 may be electrically connected to the charge storage 155. For example, the anode 10 of the sensor 100 may be a light-receiving electrode, and the cathode 20 of the sensor 100 may be electrically connected to the charge storage 155. For example, the cathode 20 of the sensor 100 may be a light-receiving electrode and the anode 10 of the sensor 100 may be electrically connected to the charge storage 155.

As described above, the sensor 100 may be configured to selectively photoelectrically convert light of a first wavelength spectrum selected from the red wavelength spectrum, green wavelength spectrum, blue wavelength spectrum, and infrared wavelength spectrum. The first wavelength spectrum may be different from the wavelength spectrum selectively transmitted by the first and second color filters 70a and 70b. For example, the first wavelength spectrum may be a green wavelength spectrum, the color filter 70a may be configured to selectively transmit light in the red wavelength spectrum, and the color filter 70b may be configured to selectively transmit light in the blue wavelength spectrum. The photoelectric conversion layer 30 of the sensor 100 may be configured to selectively absorb and convert light of the first wavelength spectrum (for example, the green wavelength spectrum), and the singlet fission material of the first and second organic auxiliary layers 35 and 37 also may be configured to absorb light of the first wavelength spectrum (e.g., green wavelength spectrum) to generate amplified excitons.

A passivation film 180 and a focusing lens (not shown) may be further formed on the sensor 100.

As described above, by having a stacked structure of a sensor 100 configured to selectively photoelectrically convert light in the first wavelength spectrum and photo-sensing elements 150a and 150b configured to sense light other than the first wavelength spectrum, the size of the image sensor may be reduced, realizing a highly integrated image sensor.

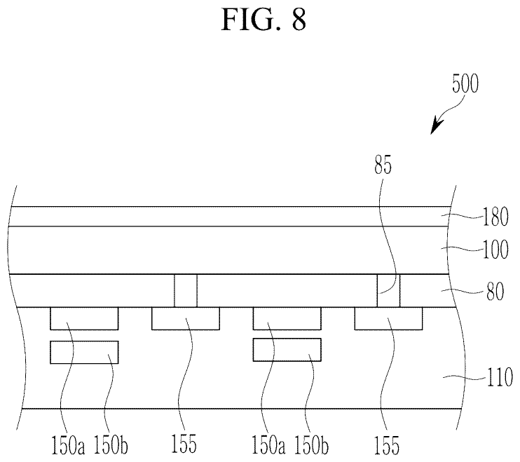

FIG. 8 is a cross-sectional view taken along the I-I line of FIG. 6 according to some example embodiments.

Referring to FIG. 8, like some example embodiments, including the aforementioned example embodiments shown in at least FIG. 7, the image sensor 500 according to some example embodiments, including the example embodiments shown in FIG. 8 includes a substrate 110 in which photo-sensing elements 150a and 150b, a transfer transistor (not shown) and a charge storage 155 are integrated, and an upper insulation layer 80, a sensor 100 and a passivation film 180.

However, in the image sensor 500 according to some example embodiments, including the example embodiments shown in FIG. 8, unlike some example embodiments, including the example embodiments shown in FIG. 7, the photo-sensing elements 150a and 150b are stacked in the vertical direction (e.g., a direction extending perpendicular to the in-plane direction of the substrate 110) and the color filter layer 70 is omitted. The photo-sensing elements 150a and 150b may be configured to selectively absorb light in each wavelength region depending on the stacking depth. The sensor 100 may have one of the structures shown in FIGS. 1 to 4, and the detailed description is the same as described above. For example, one of the anode 10 or the cathode 20 of the sensor 100 may be a light-receiving electrode disposed on the side that receives the light, and the anode 10 and the cathode 20 of the sensor 100 may be a light-receiving electrode and the other one may be electrically connected to the charge storage 155. For example, the anode 10 of the sensor 100 may be a light-receiving electrode, and the cathode 20 of the sensor 100 may be electrically connected to the charge storage 155. For example, the cathode 20 of the sensor 100 may be a light-receiving electrode and the anode 10 of the sensor 100 may be electrically connected to the charge storage 155.

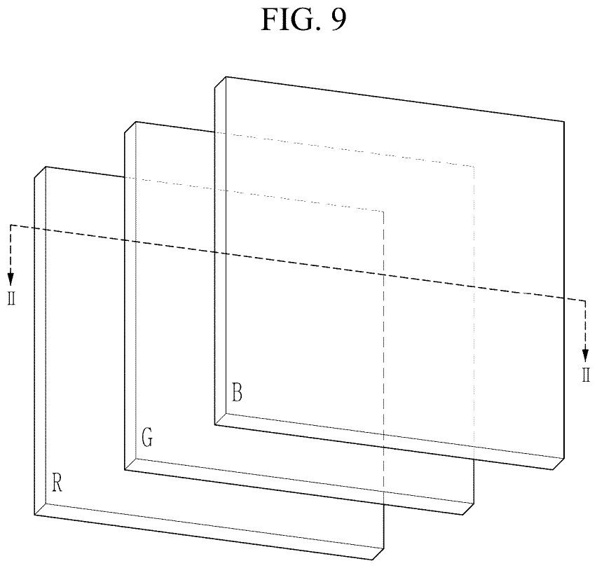

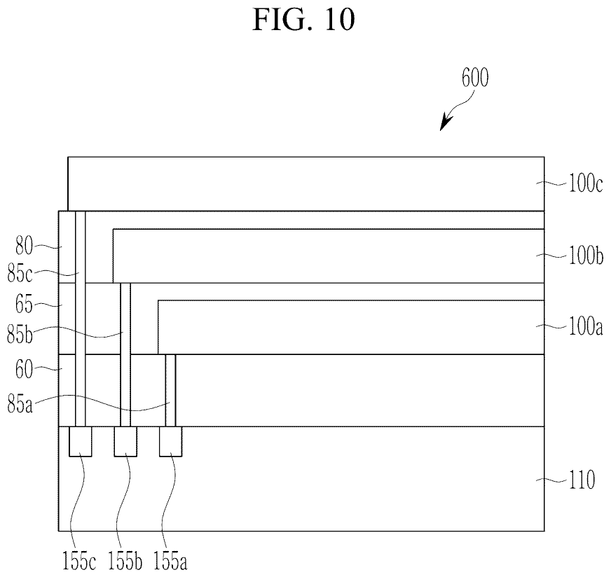

FIG. 9 is a plan view showing an image sensor according to some example embodiments, and FIG. 10 is a cross-sectional view taken along the II-II line of FIG. 9 according to some example embodiments.

The image sensor 600 according to some example embodiments, including the example embodiments shown in FIGS. 9-10, includes a first sensor 100a configured to photoelectrically convert light of a first wavelength spectrum selected from a red wavelength spectrum, a green wavelength spectrum, and a blue wavelength spectrum, a second sensor 100b configured to photoelectrically convert light of a second wavelength spectrum selected from the red wavelength spectrum, the green wavelength spectrum, and the blue wavelength spectrum, and a third sensor 100c configured to photoelectrically convert light of a third wavelength spectrum selected from the red wavelength spectrum, the green wavelength spectrum, and the blue wavelength spectrum, and the first sensor 100a, the second sensor 100b, and the third sensor 100c are stacked in the thickness direction of the substrate 110. Herein, the first wavelength spectrum, the second wavelength spectrum, and the third wavelength spectrum may be different from each other.

The image sensor 600 according to some example embodiments, including the example embodiments shown in FIGS. 9-10, includes a substrate 110, a lower insulation layer 60, an intermediate insulation layer 65, an upper insulation layer 80, a first sensor 100a, a second sensor 100b, and a third sensor 100c.

The substrate 110 may be a semiconductor substrate, for example, a silicon substrate or a compound semiconductor substrate. On the substrate 110, a transmission transistor (not shown) and charge storages 155a, 155b, and 155c are integrated for each pixel. Metal wires (not shown) and pads (not shown) are formed on the front or back of the substrate 110, and a lower insulation layer 60 is formed on the substrate 110.

The first sensor 100a, the second sensor 100b, and the third sensor 100c are sequentially formed on the lower insulation layer 60. The first, second, and third sensors 100a, 100b, and 100c may be each the aforementioned sensor 100.

The first, second, and third sensors 100a, 100b, and 100c may each independently have one of the structures shown in FIGS. 1 to 4, and detailed descriptions are as described above. One of the anode 10 or the cathode 20 of the first, second, and third sensors 100a, 100b, and 100c may be a light-receiving electrode disposed on the side receiving light, and the other of the anode 10 or the cathode 20 of the first, second, and third sensors 100a, 100b, and 100c may be electrically connected to the charge storages 155a, 155b, and 155c.

The photoelectric conversion layer 30 of the first sensor 100a may be configured to selectively absorb light of a first wavelength spectrum selected from the red wavelength spectrum, the green wavelength spectrum, and the blue wavelength spectrum and photoelectrically convert the absorbed light. The first wavelength spectrum may be, for example, a red wavelength spectrum, and the first sensor 100a may be a red sensor configured to selectively absorb light in the red wavelength spectrum and convert the absorbed light into photoelectricity.

An intermediate insulation layer 65 is formed on the first sensor 100a, and a second sensor 100b is formed on the intermediate insulation layer 65. The intermediate insulation layer 65 may be made of an inorganic insulating material such as a silicon oxide and/or a silicon nitride, or a low dielectric constant (low K) material such as SiC, SiCOH, SiCO, and SiOF.

The photoelectric conversion layer 30 of the second sensor 100b may be configured to selectively absorb light of a second wavelength spectrum selected from the red wavelength spectrum, the green wavelength spectrum, and the blue wavelength spectrum and photoelectrically convert the absorbed light. The second wavelength spectrum may be, for example, a green wavelength spectrum, and the second sensor 100b may be a green sensor configured to selectively absorb light in the green wavelength spectrum and convert the absorbed light into photoelectricity.

An upper insulation layer 80 is formed on the second sensor 100b. The lower insulation layer 60, intermediate insulation layer 65, and upper insulation layer 80 may have (e.g., define) a plurality of trenches 85a, 85b, and 85c exposing charge storages 155a, 155b, and 155c. The third sensor 100c is formed on the upper insulation layer 80.

The photoelectric conversion layer 30 of the third sensor 100c may be configured to selectively absorb light of a third wavelength spectrum selected from the red wavelength spectrum, the green wavelength spectrum, and the blue wavelength spectrum and photoelectrically convert the absorbed light. The third wavelength spectrum may be, for example, a blue wavelength spectrum, and the third sensor 100c may be a blue sensor configured to selectively absorb light in the blue wavelength spectrum and photoelectrically convert the absorbed light.

A focusing lens (not shown) may be further formed on the third sensor 100c.

In the drawing, a structure in which the first sensor 100a, the second sensor 100b, and the third sensor 100c are sequentially stacked is shown, but the stacking order is not limited to this and may vary.

As described above, the first sensor 100a, the second sensor 100b, and the third sensor 100c, which absorb light of different wavelength spectra and convert it into photoelectricity, have a stacked structure to further reduce the size of the image sensor and implement a high integration image sensor.

The aforementioned sensor 100 may be for example applied to a display panel. The sensor 100 may be embedded in a display panel as an in-cell type, and the display panel may perform both a display function and a recognition function (e.g., a biometric recognition function).

Hereinafter, an example of a display panel to which the aforementioned sensor 100 is applied will be described with reference to the drawings.

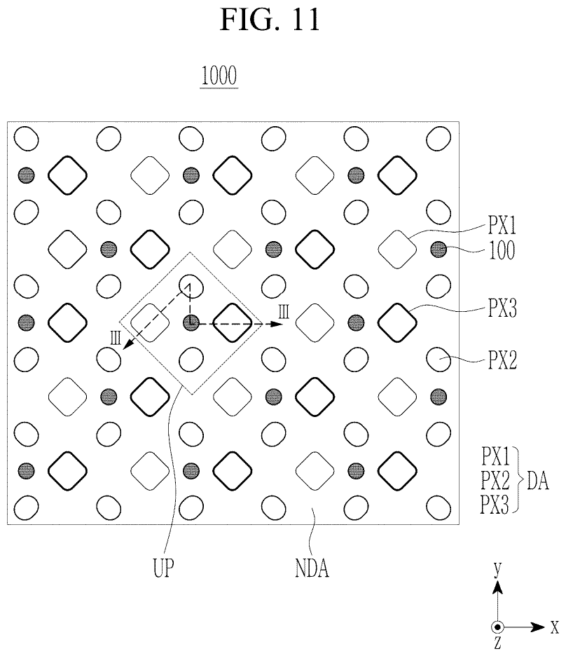

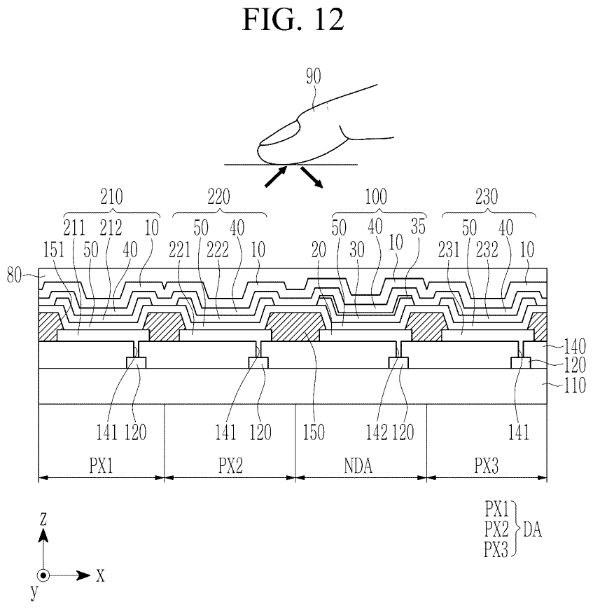

FIG. 11 is a plan view showing a sensor-embedded display panel according to some example embodiments, and FIG. 12 is a cross-sectional view showing a sensor-embedded display panel taken along the III-III line of FIG. 11 according to some example embodiments.

Referring to FIGS. 11 and 12, the display panel 1000 according to some example embodiments includes a plurality of subpixels PX1, PX2, and PX3 that display different colors. The plurality of subpixels PXs may be configured to display at least three primary colors, for example, a first subpixel PX1, a second subpixel PX2, and a third subpixel PX3 displaying different first color, second color, and third color selected from red, green, and blue. For example, the first color, the second color, and the third color may be red, green, and blue, respectively. The first subpixel PX1 may be a red subpixel displaying red, the second subpixel PX2 may be a green subpixel displaying green, and the third subpixel PX3 may be a blue subpixel displaying blue. However, the present inventive concepts are not limited thereto, and an auxiliary subpixel (not shown) such as a white subpixel may be further included.

The plurality of subpixels PXs including the first subpixel PX1, the second subpixel PX2, and the third subpixel PX3 may constitute (e.g., may define) one unit pixel UP to be arranged repeatedly along the row and/or column. In FIG. 11, a structure including one first subpixel PX1, two second subpixels PX2, and one third subpixel PX3 in the unit pixel UP is illustrated, but the present inventive concepts are not limited thereto. In some example embodiments, each unit pixel UP may include a sensor 100 as illustrated, but the present inventive concepts are not so limited thereto. At least one first subpixel PX1, at least one second subpixel PX2, and at least one third subpixel PX3 may be included in the unit pixel UP. In the drawing, as an example, an arrangement of a Pentile type is illustrated, but the present inventive concepts are not limited thereto. The subpixels PXs may be arranged variously. An area occupied by the plurality of subpixels PXs and displaying colors by the plurality of subpixels PXs may be a display area DA displaying an image. For example, the area (e.g., in the xy plane) of the subpixels PX may collectively define the display area DA that is configured to display an image thereon (e.g., configured to display one or more colors). A portion of the area (e.g., in the xy plane) of the sensor-embedded display panel 1000 that excludes the display area DA (e.g., portions of the area of the sensor-embedded display panel 1000 that are between adjacent subpixels PX in the xy direction, xy plane, etc.) may be a non-display area NDA that is configured to not display an image thereon (e.g., configured to not display any color).

Each of the first subpixel PX1, the second subpixel PX2, and the third subpixel PX3 may include a light emitting element. As an example, the first subpixel PX1 may include a first light emitting element 210 configured to emit light of a wavelength spectrum of a first color, the second subpixel PX2 may include a second light emitting element 220 configured to emit light of a wavelength spectrum of a second color, and the third subpixel PX3 may include a third light emitting element 230 configured to emit light of a wavelength spectrum of a third color. However, the present inventive concepts are not limited thereto, and at least one of the first subpixel PX1, the second subpixel PX2, or the third subpixel PX3 may include a light emitting element configured to emit light of a combination of a first color, a second color, and a third color, that is, light in a white wavelength spectrum, and may display a first color, a second color, or a third color through a color filter (not shown). Herein, the terms “wavelength spectrum” and “wavelength region” may be used interchangeably.

The display panel 1000 according to some example embodiments includes a sensor 100. The sensor 100 may be disposed in a non-display area NDA. The non-display area NDA may be an area other than the display area DA, in which the first subpixel PX1, the second subpixel PX2, the third subpixel PX3, and optionally auxiliary subpixels are not arranged (e.g., a portion of the total area of the sensor-embedded display panel 1000 that excludes the display area DA, excludes the subpixels PX, is between adjacent subpixels PX, etc.). For example, the area (e.g., in the xy plane) of the subpixels PX may collectively define the display area DA that is configured to display an image thereon (e.g., configured to display one or more colors). A portion of the area (e.g., in the xy plane) of the sensor-embedded display panel 1000 that excludes the display area DA (e.g., portions of the area of the sensor-embedded display panel 1000 that are between adjacent subpixels PX in the xy direction, xy plane, etc.) may be a non-display area NDA that is configured to not display an image thereon (e.g., configured to not display any color). The sensor 100 may be disposed between at least two subpixels selected from the first subpixel PX1, the second subpixel PX2, and the third subpixel PX3 (e.g., between at least two subpixels of a first subpixel PX1 of a plurality of first subpixels PX1, a second subpixel PX2 of the plurality of second subpixels PX2, or a third subpixel PX3 of the plurality of third subpixels PX3), and may be disposed in parallel with the first, second, and third light emitting elements 210, 220, and 230 in the display area DA for example in parallel along the in-plane direction of the substrate 110 (e.g., the xy direction as shown), which may be a direction extending parallel to an upper surface of the substrate 110.

The sensor 100 may be an optical type recognition sensor (e.g., a biometric sensor). The sensor 100 may be configured to absorb light generated by reflection of light emitted from at least one of the first, second, or third light emitting elements 210, 220, or 230 disposed in the display area DA, by a recognition target 90 such as a living body, a tool, or a thing (e.g., may be configured to absorb light of a red wavelength spectrum, a green wavelength spectrum, a blue wavelength spectrum, an infrared wavelength spectrum, or any combination thereof), and then may convert it (the absorbed light) into an electrical signal. Herein, the living body may be a finger, a fingerprint, a palm, an iris, a face, and/or a wrist, but is not limited thereto. The sensor 100 may be, for example, a fingerprint sensor, an illumination sensor, an iris sensor, a distance sensor, a blood vessel distribution sensor, and/or a heart rate sensor, but is not limited thereto.

The sensor 100 may be disposed on the same plane as the first, second, and third light emitting elements 210, 220, and 230 on the substrate 110, and may be embedded in the display panel 1000. Restated, the sensor 100 may be in parallel with the first, second, and third light emitting elements 210, 220, and 230 on the substrate 110 along an in-plane direction of the substrate 110. As described herein, the in-plane direction of the substrate 110 may be a direction (e.g., the xy direction as shown) that extends in parallel with at least a portion of the substrate 110, including an upper surface of the substrate 110.

Referring to FIG. 12, the display panel 1000 includes a substrate 110; a thin film transistor 120 on the substrate 110; an insulation layer 140 on the thin film transistor 120; a pixel definition layer 150 on the insulation layer 140; and first, second, and third light emitting elements 210, 220, and 230 and the sensor 100 in a space partitioned by the pixel definition layer 150.

The substrate 110 may be a light transmitting substrate, for example, a glass substrate or a polymer substrate. The polymer substrate may include, for example, polycarbonate, polymethylmethacrylate, polyethyleneterephthalate, polyethylenenaphthalate, polyimide, polyamide, polyamideimide, polyethersulfone, polyorganosiloxane, a styrene-ethylene-butylene-styrene copolymer, polyurethane, polyacrylate, polyolefin, or any combination thereof, but is not limited thereto.

A plurality of thin film transistors 120 are formed on the substrate 110. One or more thin film transistors 120 may be included in each subpixel PX, and may include, for example, at least one switching thin film transistor and/or at least one driving thin film transistor. The substrate 110 on which the thin film transistor 120 is formed may be referred to as a thin film transistor substrate (TFT substrate) or a thin film transistor backplane (TFT backplane).

The insulation layer 140 may cover the substrate 110 and the thin film transistor 120 and may be formed on the whole surface of the substrate 110. The insulation layer 140 may be a planarization layer or a passivation layer, and may include an organic insulating material, an inorganic insulating material, an organic-inorganic insulating material, or any combination thereof. The insulation layer 140 may have (e.g., define) a plurality of contact holes 141 for electrically connecting the first, second, and third light emitting elements 210, 220, and 230 and the thin film transistor 120 and a plurality of contact holes 142 for electrically connecting the sensor 100 and the thin film transistor 120. The insulation layer 140 may include an inorganic material, an organic material, an inorganic material, or any combination thereof. The inorganic material may be, for example, silicon oxide, silicon nitride, silicon oxynitride, aluminum oxide, or aluminum nitride, the organic material may be, for example, polyimide, polyamide, polyamideimide, or polyacrylate, and the organic material may be, for example, polyorganosiloxane, or polyorganosilazane.

The pixel definition layer 150 may also be formed on the whole surface of the substrate 110 and may be disposed between adjacent subpixels PXs to partition each subpixel PX. The pixel definition layer 150 may have a plurality of openings 151 disposed in each subpixel PX, and in each opening 151, any one of first, second, and third light emitting elements 210, 220, and 230 and the sensors 100 may be disposed. The pixel definition layer 150 may include an inorganic material, an organic material, an inorganic material, or any combination thereof. The inorganic material may be, for example, silicon oxide, silicon nitride, silicon oxynitride, aluminum oxide, or aluminum nitride, the organic material may be, for example, polyimide, polyamide, polyamideimide, or polyacrylate, the organic/inorganic material may be, for example, polyorganosiloxane or polyorganosilazane.

The first, second and third light emitting elements 210, 220, and 230 are formed on the substrate 110 (or thin film transistor substrate), and are repeatedly arranged along the in-plane direction (e.g., xy direction) of the substrate 110 to form a light emitting element array. As described above, the first, second, and third light emitting elements 210, 220, and 230 may be included in the first subpixel PX1, the second subpixel PX2, and the third subpixel PX3, respectively. The first, second, and third light emitting elements 210, 220, and 230 may be electrically connected to separate thin film transistors 120 and may be driven independently.

The first, second, and third light emitting elements 210, 220, and 230 may be configured to each independently emit one light of a red wavelength spectrum, a green wavelength spectrum, a blue wavelength spectrum, or any combination thereof. For example, the first light emitting element 210 may be configured to emit light of a red wavelength spectrum, the second light emitting element 220 may be configured to emit light of a green wavelength spectrum, and the third light emitting element 230 may be configured to emit light of a blue wavelength spectrum. Herein, the red wavelength spectrum, the green wavelength spectrum, and the blue wavelength spectrum may have a maximum emission wavelength (λ_{peak,L}) in a wavelength region of greater than about 600 nm and less than about 750 nm, about 500 nm to about 600 nm, and greater than or equal to about 400 nm and less than about 500 nm, respectively.

The first, second, and third light emitting elements 210, 220, and 230 may be, for example, light emitting diodes, for example organic light emitting diodes (OLEDs) including an organic light emitting material.

The sensor 100 may be formed on the substrate 110 (or the thin film transistor substrate), and may be randomly or regularly arranged along the in-plane direction (e.g., xy direction) of the substrate 110. As described above, the sensor 100 may be disposed in the non-display area NDA, and may be connected to a separate thin film transistor 120 to be independently driven.

The sensor 100 may be configured to absorb light belonging to a wavelength spectrum of the light emitted from at least one of the first, second, and third light emitting elements 210, 220, and 230 and then convert it into an electrical signal. For example, the sensor 100 may be configured to absorb light of a red wavelength spectrum and a green wavelength spectrum, a blue wavelength spectrum, and any combination thereof, and then convert it into an electrical signal and for example, light of a green wavelength spectrum may be absorbed and converted into an electrical signal.

Each of the first, second, and third light emitting elements 210, 220, and 230 and the sensor 100 may include a pixel electrode 211, 221, 231, and 20; a common electrode 10 facing the pixel electrodes 211, 221, 231, and 20 and to which a common voltage is applied; and light emitting layers 212, 222, and 232 or a photoelectric conversion layer 30, a first common auxiliary layer 40, and a second common auxiliary layer 50 between the pixel electrode 211, 221, 231, and 20 and the common electrode 10.

The common electrode 10 of the sensor 100 may be the anode 10 of the sensor 100 shown in FIGS. 1 to 4, and the pixel electrode 20 of the sensor 100 may be the cathode 20 of the sensor 100 shown in FIGS. 1 to 4. The photoelectric conversion layer 30 of the sensor 100 may be the photoelectric conversion layer 30 of the sensor 100 shown in FIGS. 1 to 4. The first common auxiliary layer 40 of the sensor 100 may be the hole auxiliary layer 40 of the sensor 100 shown in FIGS. 2 and 4 and the second common auxiliary layer 50 of the sensor 100 may be the electron auxiliary layer 50 of the sensor 100 shown in FIGS. 2 and 4. The sensor 100, as depicted in FIG. 12, may further include the first organic auxiliary layer 35 between the common electrode 10 and the photoelectric conversion layer 30, or between the first common auxiliary layer 40 and the photoelectric conversion layer 30, and the descriptions of the first organic auxiliary layers 35 is the same as described above.

The first, second, and third light emitting elements 210, 220, and 230 and the sensor 100 may be arranged in parallel along the in-plane direction (e.g., xy direction) of the substrate 110, and may share the common electrode 10, the first common auxiliary layer 40, and the second common auxiliary layer 50 which are formed on the whole surface of the substrate 110.

The common electrode 10 is continuously formed as a single piece of material that extends on the light emitting layers 212, 222, and 232 and the photoelectric conversion layer 30, and is formed substantially on the whole surface of the substrate 110. The common electrode 10 may apply a common voltage to the first, second, and third light emitting elements 210, 220, and 230 and the sensor 100. As shown, the first, second, and third light emitting elements 210, 220, and 230 and the sensor 100 may include separate portions of a single common electrode 10 that is a single piece of material that extends on each of the respective light emitting layers 212, 222, and 232 and the photoelectric conversion layer 30 and between the first, second, and third light emitting elements 210, 220, and 230 and the sensor 100.

The first common auxiliary layer 40 may be between the light emitting layers 212, 222, 232 and the photoelectric conversion layer 30, and the substrate 110, and among them, between the light emitting layers 212, 222, 232 and the photoelectric conversion layer 30, and the common electrodes 10. The first common auxiliary layer 40 may be continuously formed by being connected to each other on the lower portion of the light emitting layers 212, 222, 232 and the photoelectric conversion layer 30 and on the upper portion of the common electrode 10. As shown, the first, second, and third light emitting elements 210, 220, and 230 and the sensor 100 may include separate portions of a single first common auxiliary layer 40 that is a single piece of material that extends on each of the respective light emitting layers 212, 222, and 232 and the photoelectric conversion layer 30 and between the first, second, and third light emitting elements 210, 220, and 230 and the sensor 100. The first common auxiliary layer 40 may be a hole auxiliary layer that facilitates injection and/or movement of holes from the common electrode 10 to the light emitting layers 212, 222, and 232. The first common auxiliary layer 40 may include a hole transport material. For example, the HOMO energy level of the first common auxiliary layer 40 (e.g., electron transport material) may be between the HOMO energy level of the light emitting layers 212, 222, and 232 (the HOMO energy level of the organic light emitting material of the light emitting layer) and the work functions of the common electrode 10. The work functions of the common electrode 10, the HOMO energy levels of the first common auxiliary layer 40, and the HOMO energy levels of the light emitting layers 212, 222, and 232 may be sequentially deepened. For example, the HOMO energy level of the first common auxiliary layer 40 (e.g., hole transport material) may be about 5.3 eV to about 5.6 eV, and may be about 5.3 eV to about 5.5 eV within the above range, but is not limited thereto.

The second common auxiliary layer 50 may be between the light emitting layers 212, 222, 232 and the photoelectric conversion layer 30, and the substrate 110, and among them, between the light emitting layers 212, 222, 232 and the photoelectric conversion layer 30, and the pixel electrodes 211, 221, 231, and 20. The second common auxiliary layer 50 may be continuously formed as a single piece of material that extends on the lower portions of the light emitting layers 212, 222, and 232 and the photoelectric conversion layer 30 and on the upper portions of pixel electrodes 211, 221, 231, and 20. As shown, the first, second, and third light emitting elements 210, 220, and 230 and the sensor 100 may include separate portions of a single second common auxiliary layer 50 that is a single piece of material that extends under each of the respective light emitting layers 212, 222, and 232 and the photoelectric conversion layer 30 and between the first, second, and third light emitting elements 210, 220, and 230 and the sensor 100.

The second common auxiliary layer 50 may be a charge auxiliary layer (e.g., electron auxiliary layer) that facilitates injection and/or movement of charge carriers (e.g., electrons) from the pixel electrodes 211, 221, and 231 to the light emitting layers 212, 222, and 232. The second common auxiliary layer 50 may include a charge transport material, for example, an electron transport material. For example, the LUMO energy level of the second common auxiliary layer 50 (e.g., electron transport material) may be between the LUMO energy level of the light emitting layers 212, 222, and 232 (the LUMO energy level of the organic light emitting material of the light emitting layer) and the work functions of the pixel electrodes 211, 221, and 231 (conductor of the pixel electrode). The work functions of the pixel electrodes 211, 221, and 231, the LUMO energy levels of the second common auxiliary layer 50, and the LUMO energy levels of the light emitting layers 212, 222, and 232 may be sequentially shallowed. For example, the LUMO energy level of the second common auxiliary layer 50 (e.g., hole transport material) may be about 2.9 eV to about 3.3 eV, and may be about 2.9 eV to about 3.2 eV, about 2.9 eV to about 3.1 eV, about 3.0 eV to about 3.2 eV, or about 3.0 eV to about 3.1 eV within the above range, but is not limited thereto.

Each of the first, second, and third light emitting elements 210, 220, and 230 and the sensor 100 includes a separate pixel electrode 211, 221, 231, or 20 facing the common electrode 10. For example, the pixel electrodes 211, 221, 231, and 20 may be a cathode, and the common electrode 10 may be an anode. The pixel electrodes 211, 221, 231, and 20 are separated for each subpixel PX, and are electrically connected to each separate thin film transistor 120 to be independently driven.

The pixel electrodes 211, 221, 231, and 20 may be a light transmitting electrode (a transparent electrode or a semi-transmissive electrode) or a reflective electrode. For example, when the pixel electrodes 211, 221, 231, and 20 are reflective electrodes and the common electrode 10 is a light transmitting electrode, the sensor-embedded display panel 1000 may be a top emission type display panel configured to emit light toward the opposite side of the substrate 110. For example, when each of the pixel electrodes 211, 221, 231, and 20 and the common electrode 10 are light transmitting electrodes, the sensor-embedded display panel 1000 may be a both side emission type display panel configured to emit light toward both the substrate 110 and the opposite side of the substrate 110.

For example, the pixel electrodes 211, 221, 231, and 20 may be reflective electrodes and the common electrode 10 may be a semi-transmissive electrode. In this case, the sensor-embedded display panel 1000 may have a microcavity structure. In the microcavity structure, reflection may occur repeatedly between the reflective electrode and the semi-transmissive electrode (e.g., between the pixel electrodes 211, 221, 231, and 20 and the common electrode 10) separated by a particular (or, alternatively, predetermined) optical length (e.g., a distance between the semi-transmissive electrode and the reflective electrode) and light of a particular (or, alternatively, predetermined) wavelength spectrum may be enhanced to improve optical properties.

For example, among the light emitted from the light emitting layers 212, 222, and 232 of the first, second, and third light emitting elements 210, 220, and 230, light of a particular (or, alternatively, predetermined) wavelength spectrum may be repeatedly reflected between the semi-transmissive electrode and the reflective electrode and then may be modified. Among the modified light, light of a wavelength spectrum corresponding to a resonance wavelength of a microcavity may be enhanced to exhibit amplified light emission characteristics in a narrow wavelength region. Accordingly, the sensor-embedded display panel 1000 may express colors with high color purity.

For example, among the light incident on the sensor 100, light of a particular (or, alternatively, predetermined) wavelength spectrum may be repeatedly reflected between the semi-transmissive electrode and the reflective electrode to be modified. Among the modified light, light having a wavelength spectrum corresponding to the resonance wavelength of a microcavity may be enhanced to exhibit photoelectric conversion characteristics amplified in a narrow wavelength region. Accordingly, the sensor 100 may exhibit high photoelectric conversion characteristics in a narrow wavelength region.

Each of the first, second, and third light emitting elements 210, 220, and 230 includes light emitting layers 212, 222, and 232 between the pixel electrodes 211, 221, and 231 and the common electrode 10. Each of the light emitting layer 212 included in the first light emitting element 210, the light emitting layer 222 included in the second light emitting element 220, and the light emitting layer 232 included in the third light emitting element 230 may be configured to emit light in the same or different wavelength spectra and may be configured to emit light in, for example a red wavelength spectrum, a green wavelength spectrum, a blue wavelength spectrum, or any combination thereof.

For example, when the first light emitting element 210, the second light emitting element 220, and the third light emitting element 230 are a red light emitting element, a green light emitting element, and a blue light emitting element, respectively, the light emitting layer 212 included in the first light emitting element 210 may be a red light emitting layer configured to emit light in a red wavelength spectrum, the light emitting layer 222 included in the second light emitting element 220 may be a green light emitting layer configured to emit light in a green wavelength spectrum, and the light emitting layer 232 included in the third light emitting element 230 may be a blue light emitting layer configured to emit light in a blue wavelength spectrum. Herein, the red wavelength spectrum, the green wavelength spectrum, and the blue wavelength spectrum may have a peak emission wavelength (λ_{peak,L}) of greater than about 600 nm and less than about 750 nm, about 500 nm to about 600 nm, and greater than or equal to about 380 nm and less than about 500 nm, respectively.

For example, when at least one of the first light emitting element 210, the second light emitting element 220, or the third light emitting element 230 is a white light emitting element, the light emitting layer of the white light emitting element may be configured to emit light of a full visible light wavelength spectrum, for example, light in a wavelength spectrum of greater than or equal to about 380 nm and less than about 750 nm, about 400 nm to about 700 nm, or about 420 nm to about 700 nm.

The light emitting layers 212, 222, and 232 may include at least one host material and a fluorescent or phosphorescent dopant, and at least one of the at least one host material and the fluorescent or phosphorescent dopant may be an organic light emitting material. The organic light emitting material may include, for example, a low molecular organic light emitting material, for example, a vapor depositable organic light emitting material.

The organic light emitting material included in the light emitting layers 212, 222, and 232 is not particularly limited as long as it is an electroluminescent material capable of emitting light of a particular (or, alternatively, predetermined) wavelength spectrum, and may be, for example, perylene; rubrene; 4-(dicyanomethylene)-2-methyl-6-[p-(dimethylamino)styryl]-4H-pyran; coumarin or any derivative thereof; carbazole or any derivative thereof; TPBi (2,2′,2″-(1,3,5-benzinetriyl)-tris(1-phenyl-1-H-benzimidazole); TBADN (2-t-butyl-9,10-di(naphth-2-yl)anthracene); AND (9,10-di(naphthalene-2-yl)anthracene); CBP (4,4′-bis(N-carbazolyl)-1,1′-biphenyl); TCTA (4,4′,4″-tris(carbazol-9-yl)-triphenylamine); TPBi (1,3,5-tris(N-phenylbenzimidazole-2-yl)benzene); TBADN (3-tert-butyl-9,10-di(naphth-2-yl)anthracene); DSA (distyrylarylene); CDBP (4,4′-bis(9-carbazolyl)-2,2′-dimethyl-biphenyl); MADN (2-methyl-9,10-bis(naphthalen-2-yl)anthracene); TCP (1,3,5-tris(carbazol-9-yl)benzene); Alq3 (tris(8-hydroxyquinolino)lithium); an organometallic compound including Pt, Os, Ti, Zr, Hf, Eu, Tb, Tm, Rh, Ru, Re, Be, Mg, Al, Ca, Mn, Co, Cu, Zn, Ga, Ge, Pd, Ag, and/or Au, any derivative thereof, or any combination thereof, but is not limited thereto.

The organic light emitting material included in the light emitting layers 212, 222, and 232 may be a depositable organic light emitting material that may be vaporized (sublimated) at a particular (or, alternatively, predetermined) temperature to be deposited, and may have a particular (or, alternatively, predetermined) sublimation temperature (Ts). Herein, the sublimation temperature may be a temperature at which a weight loss of 10% relative to the initial weight occurs during thermogravimetric analysis (TGA) at a low pressure of about 10 Pa or less, and may be a deposition temperature during the process or a set temperature of a deposition chamber used in the process.

The sublimation temperature (Ts) of the organic light emitting material included in the light emitting layer 212, 222, and 232 may be less than or equal to about 350° C., and within the above range, less than or equal to about 340° C., less than or equal to about 330° C., less than or equal to about 320° C., less than or equal to about 310° C., less than or equal to about 300° C., less than or equal to about 290° C., less than or equal to about 280° C., less than or equal to about 270° C., or less than or equal to about 250° C., about 100° C. to about 350° C., about 100° C. to about 340° C., about 100° C. to about 330° C., about 100° C. to about 320° C., about 100° C. to about 310° C., about 100° C. to about 300° C., about 100° C. to about 290° C., about 100° C. to about 280° C., about 100° C. to about 270° C., about 100° C. to about 260° C., about 100° C. to about 250° C., about 150° C. to about 350° C., about 150° C. to about 340° C., about 150° C. to about 330° C., about 150° C. to about 320° C., about 150° C. to about 310° C., about 150° C. to about 300° C., about 150° C. to about 290° C., about 150° C. to about 280° C., about 150° C. to about 270° C., about 150° C. to about 260° C., or about 150° C. to about 250° C. When the organic light emitting material has a sublimation temperature within the above range, it may be effectively deposited without substantial decomposition and/or deterioration of the organic light emitting material.

The sensor 100 includes a photoelectric conversion layer 30 between the pixel electrode 20 and the common electrode 10. The photoelectric conversion layer 30 may be between the first common auxiliary layer 40 and the second common auxiliary layer 50. The photoelectric conversion layer 30 is disposed in parallel with the light emitting layers 212, 222, and 232 of the first, second, and third light emitting elements 210, 220, and 230 along the in-plane direction (e.g., xy direction) of the substrate 110. The photoelectric conversion layer 30 and the light emitting layers 212, 222, and 232 may be disposed on the same plane. The description of the photoelectric conversion layer 30 is the same as described above.

The sensor 100 includes the first organic auxiliary layer 35 between the common electrode 10 and the photoelectric conversion layer 30. The first organic auxiliary layers 35, as described above, may include a singlet fission material to absorb light of a particular (or, alternatively, predetermined) wavelength spectrum, which splits from the excited singlet state (S₁) to the triplet state (T₁) to produce (e.g., about twice) amplified excitons, wherein the amplified excitons are combined with the excitons produced in the photoelectric conversion layer 30 to increase charges and thus increase efficiency of the sensor. Accordingly, external quantum efficiency (EQE) and/or internal quantum efficiency (IQE) of the sensor 100 may be theoretically greater than 100%. The first organic auxiliary layer 35 may be the same as described above.

Although FIG. 12 illustrates an example in which the sensor 100 shown in FIG. 2 is included as an example, the sensor 100 shown in FIG. 4 may be included without being limited thereto.

The aforementioned display panel 1000 may be applied to electronic devices such as various display devices. Electronic devices such as display devices may be applied to, for example, mobile phones, video phones, smart phones, mobile phones, smart pads, smart watches, digital cameras, tablet PCs, laptop PCs, notebook computers, computer monitors, wearable computers, televisions, digital broadcasting terminals, e-books, personal digital assistants (PDAs), portable multimedia player (PMP), enterprise digital assistant (EDA), head mounted display (HMD), vehicle navigation, Internet of Things (IoT), Internet of all things (IoE), drones, door locks, safes, automatic teller machines (ATM), security devices, medical devices, or automotive electronic components, but are not limited thereto.

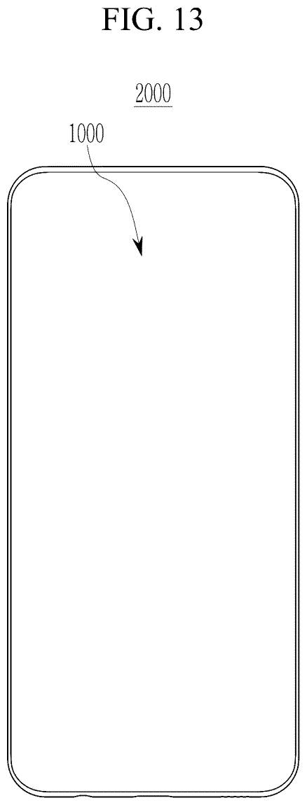

FIG. 13 is a schematic view showing a smart phone as an electronic device according to some example embodiments.

Referring to FIGS. 12 and 13, the electronic device 2000 may include the aforementioned display panel 1000, and the sensor 100 on the whole or a portion of the display panel 1000, and thus a biometric recognition function may be performed by absorbing light of a certain wavelength spectrum from any portion of the screen and converting it into an electrical signal, or, depending on the user's choice, the biometric recognition function may be selectively performed only at a specific location where the biometric recognition function is required.

An example of a method of recognizing the recognition target 90 in an electronic device 2000 such as a display device may include, for example, driving the first, second, and third light emitting elements 210, 220, and 230 of the display panel 1000 and the sensor 100 to sense the light reflected from the recognition target 90 among the light emitted from the first, second, and third light emitting elements 210, 220, and 230, in the sensor 100; comparing the image of the recognition target 90 stored in advance with the image of the recognition target 90 sensed by the sensor 100; and judging the consistency of the compared images and if they match according to the determination that recognition of the recognition target 90 is complete, turning off the sensor 100, permitting user's access to the display device, and driving the display panel 1000 to display an image.

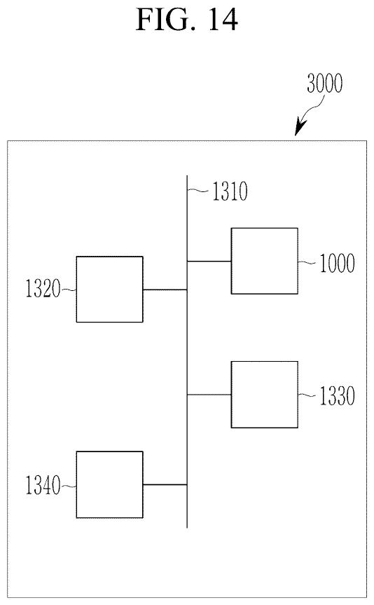

FIG. 14 is a schematic view illustrating an electronic device according to some example embodiments.

Referring to FIG. 14, in addition to the aforementioned constituent elements, the electronic device 3000 may further include a bus 1310, a processor 1320, a memory 1330, and at least one additional device 1340. Information of the aforementioned display panel 1000, processor 1320, memory 1330, and at least one additional device 1340 may be transmitted to each other through the bus 1310.

The processor 1320 may include one or more processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. As an example, the processing circuitry may include a non-transitory computer readable storage device. The processor 1320 may, for example, control a display operation of the display panel 1000 or control a sensor operation of the sensor 100.

The memory 1330 may store an instruction program, and the processor 1320 may perform a function related to the display panel 1000 by executing the stored instruction program.

The at least one additional device 1340 may be one or more communication interfaces (e.g., wireless communication interfaces, wired interfaces), user interfaces (e.g., keyboard, mouse, buttons, etc.), power supply and/or power supply interfaces, or any combination thereof.

The units and/or modules described herein may be implemented using hardware constituent elements and software constituent elements. For example, the hardware constituent elements may include microphones, amplifiers, band pass filters, audio-to-digital converters, and processing devices. The processing device may be implemented using one or more hardware devices configured to perform and/or execute program code by performing arithmetic, logic, and input/output operations. The processing device may include a processor, a controller and an arithmetic logic unit, a digital signal processor, a microcomputer, a field programmable array, a programmable logic unit, a microprocessor, or any other device capable of responding to and executing instructions. The processing device may access, store, operate, process, and generate data in response to execution of an operating system (OS) and one or more software running on the operating system.

The software may include a computer program, a code, an instruction, or any combination thereof, and may transform a processing device for a special purpose by instructing and/or configuring the processing device independently or collectively to operate as desired. The software and data may be implemented permanently or temporarily as signal waves capable of providing or interpreting instructions or data to machines, parts, physical or virtual equipment, computer storage media or devices, or processing devices. The software may also be distributed over networked computer systems so that the software may be stored and executed in a distributed manner. The software and data may be stored by one or more non-transitory computer readable storage devices.

As described herein, any devices, systems, modules, portions, units, controllers, circuits, and/or portions thereof according to any of the example embodiments, and/or any portions thereof (including, without limitation, display panel 1000, bus 1310, processor 1320, memory 1330, and at least one additional device 1340, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

The method according to the foregoing example embodiments may be recorded in a non-transitory computer readable storage device including program instructions for implementing various operations of the aforementioned embodiments. The storage device may also include program instructions, data files, data structures, and the like alone or in combination. The program instructions recorded in the storage device may be specially designed for the present example embodiments or may be known to those skilled in computer software and available for use. Examples of non-transitory computer-readable storage devices may include magnetic media such as hard disks, floppy disks, and magnetic tapes; optical media such as CD-ROM discs, DVDs and/or blue-ray discs; magneto-optical media such as optical disks; and a hardware device configured to store and execute program instructions such as ROM, RAM, flash memory, and the like. The aforementioned device may be configured to operate as one or more software modules to perform the operations of any of the aforementioned example embodiments.

The aforementioned sensor 100 or the display panel 1000 also may be applied to an optical communication device as one example of an electronic device.

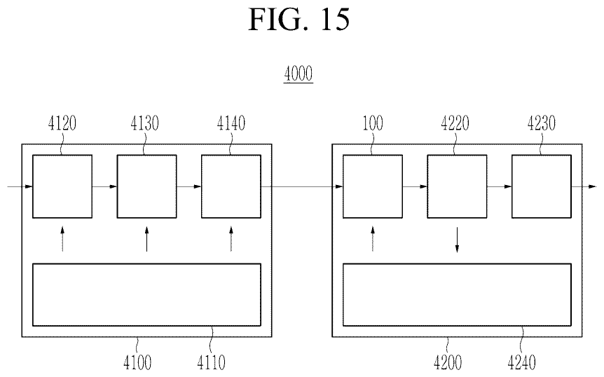

FIG. 15 is a schematic view showing an optical communication device as an electronic device according to some example embodiments.

Referring to FIG. 15, an optical communication device 4000 according to some example embodiments may include a transmitter 4100 and a receiver 4200. The transmitter 4100 may include a controller 4110, an encoder 4120, a pre-equalizer 4130, and a driver 4140. The receiver 4200 may include the aforementioned sensor 100 (or the display panel 1000, the image sensor 300, the image sensor 400, the image sensor 500, the image sensor 600), a machine learning demodulator 4220, a decoder 4230, and a signal-to-interference and noise ratio (SINR) estimator 4240.

The controller 4110 of the transmitter 4100 may determine a transmission parameter for encoding, equalizing, and optical signal driving and transmit the determined transmission parameter to the encoder 4120, the pre-equalizer 4130, and the driver 4140. The transmission parameter determined by the controller 4110 may include a modulation level for the encoding, an equalization parameter for the pre-equalizing, and a modulation depth for the optical signal driving. For example, the controller 4110, which receives a feedback of the estimated SINR of the received signals from the receiver 4200, may adjust the modulation level, the equalization parameter, and the modulation depth based on the received SINR feedback and then, transmit the adjusted modulation level, equalization parameter, and modulation depth to the encoder 4120, the pre-equalizer 4130, and the driver 4140.

The encoder 4120 of the transmitter 4100 may encode a bit string to be transmitted to the receiver 4200 according to a modulation level determined by the controller 4110 to generate encoded signals. The pre-equalizer 4130 of the transmitter 4100 may reinforce some frequency bands of the encoded signals to supplement reception characteristics of the sensor 100. The pre-equalizer 4130 may enhance a band corresponding to an enhanced bandwidth (i.e., pre-equalization parameter) determined by the controller 4110 in the encoded signals. The pre-equalizer 4130 may pre-equalize the optical signals based on a particular (or, alternatively, predetermined) equalization bandwidth (equalization parameter) and then, re-equalize (i.e., re-pre-equalize) the optical signals according to an adjusted equalization bandwidth based on the SINR feedback from the receiver 4200.

The driver 4140 of the transmitter 4100 may modulate electric signals depending on a modulation depth determined by the controller 4110 and drive the modulated signals to a light source (LED or laser, etc.). Subsequently, the light source driven by the driver 4140 may output the optical signals.

The sensor 100 of the receiver 4200 may be configured to convert light received from transmitter 4100 to electrical signals. The sensor 100 may be configured to convert light of different wavelength spectra sequentially or simultaneously to the electrical signals. If the light of different wavelength spectra is sequentially received by the receiver 4200, the sensor 100 may generate electrical signals according to each wavelength spectrum through the photoelectric conversion layer 30 corresponding to each wavelength spectrum. Or, if the light of different wavelength spectra simultaneously reach the receiver 4200, the sensor 100 may generate electrical signals according to each wavelength spectrum through the photoelectric conversion layer 30 corresponding to each wavelength spectrum. The sensor 100 may have the same structure as described above and exhibit further improved sensitivity by the first organic auxiliary layers 35 including the singlet fission material.

The ML demodulator 4220 of the receiver 4200 may demodulate original signals by using an ML model learned through sample data from the electrical signals converted by the sensor 100. The decoder 4230 of the receiver 4200 may decode bits from the demodulated electric signals. The SINR estimator 4240 of the receiver 4200 may estimate SINR of light from the demodulated electrical signals and then, feedback the estimated SINR to the transmitter 4100.

Hereinafter, some example embodiments are illustrated in more detail with reference to examples. However, the present scope of the inventive concepts is not limited to these examples.

### EXAMPLES

### Synthesis Example 1: Synthesis of 5,11-di(thiophen-2-yl)tetracene (2T-Tc)

The rubrene derivative, 5,11-di(thiophen-2-yl)tetracene (2T-Tc) was synthesized using Stille cross-coupling reactions, followed by NBS bromination of tetracene, as depicted in Reaction Scheme 1 below.

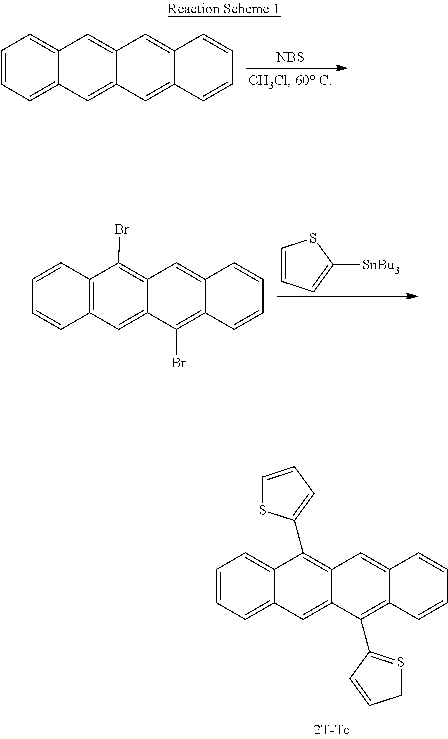

Specifically, Tetracene (0.30 g, 1.3 mmol) was dissolved in 270 mL of CHCl₃. Following the addition of N-bromosuccinimide (0.47 g, 2.6 mmol) to the tetracene solution, the reaction mixture was then heated overnight at 60° C. The organic layer was washed with water and recrystallized by heating, yielding a bright red solid powder, 5,11-dibromotetracene (Br₂-Tc) (0.39 g, Yield 59%). ¹H NMR (500 MHz, CD₂Cl₂) δ 9.29 (s, 2H), 8.50 (d, J=9.0 Hz, 2H), 8.13 (d, J=8.5 Hz, 2H), 7.63-7.58 (m, 2H), 7.54-7.51 (m, 2H). MALDI-TOF: m/z calculated: 385.913 [M]+; found: 385.811 [M]+

The introduction of a thiophenyl group to tetracene was achieved through the use of the obtained compound 5,11-dibromotetracene (Br₂—Tc) and tributyl(thiophen-2-yl)stannane via a Stille reaction. ¹H NMR (500 MHz, CD₂Cl₂) δ 8.60 (s, 2H), 7.89 (d, J=7.0 Hz, 2H), 7.81 (d, J=7.5 Hz, 2H), 7.73 (d, J=5.0 Hz, 2H), 7.41 (dd, J=5.0 Hz, 2H), 7.38-7.34 (m, 4H) 7.31 (d, J=3.5 Hz, 2H). Decomposition (10% weight loss at 10 Pa) temperature: 143° C. MALDI-TOF: m/z calculated: 392.069 [M]+; found: 391.973 [M]+

The following experiments were performed by using 5,11-di(thiophen-2-yl)tetracene (2T-Tc), which was synthesized by the reaction as described above, procured from AnyChemTech.

### Synthesis Example 2: Synthesis of 5,6,11,12-tetra(thiophen-2-yl)tetracene (4T-Tc)

Through a reaction similar to Synthesis Example 1, 5,6,11,12-tetra(thiophen-2-yl)tetracene (4T-Tc) was synthesized as described in Reaction Scheme 2 below.

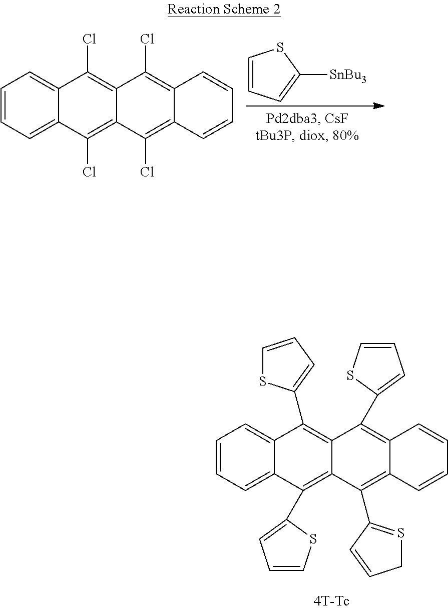

The starting material, 4,5,10,11-tetrachloroyltetracene, was purchased from Medigen, Inc., and the solvent, dioxane, was a chromatographic grade, and purchased from Sigma-Aldrich Co., Ltd., and used as provided. The final product, 5,6,11,12-tetra(thiophen-2-yl)tetracene (4T-Tc) was obtained in red solid. ¹H NMR (500 MHz, CD₂Cl₂) δ 7.63 (d, 4H), 7.32 (d, 4H), 7.25 (dd, 4H), 6.90 (dd, 4H), 6.70 (s, 4H). Decomposition (10% weight loss at 10 Pa) temperature: 218° C. MALDI-TOF: m/z calculated: 556.045 [M]+; found: 556.045 [M]+

### Experimental Examples: Fabricating Thin Film and Evaluation

### (1) Sample Preparation

The toluene solutions of 4P-Tc (Rubrene) purchased by ACROS Organics B.V.B.A. and represented by the chemical formula depicted below, 2T-Tc synthesized in Synthesis Example 1, and 4T-Tc synthesized in Synthesis Example 2 were prepared in ambient conditions and purged with Ar gas prior to experiments. HPLC-grade and anhydrous solvents were purchased from Sigma-Aldrich and used without further purification.

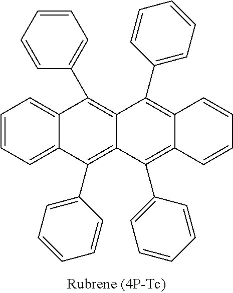 [SMILES: c1ccc(-c2c3ccccc3c(-c3ccccc3)c3c(-c4ccccc4)c4ccccc4c(-c4ccccc4)c23)cc1]

Thin films were prepared by depositing each of the toluene solutions to have a thickness of 150 nm on quartz and sapphire substrates. Prepared films were transferred to a nitrogen-filled glovebox and encapsulated using a glass coverslip and epoxy resin.

### (2) Steady-State Optical Measurements

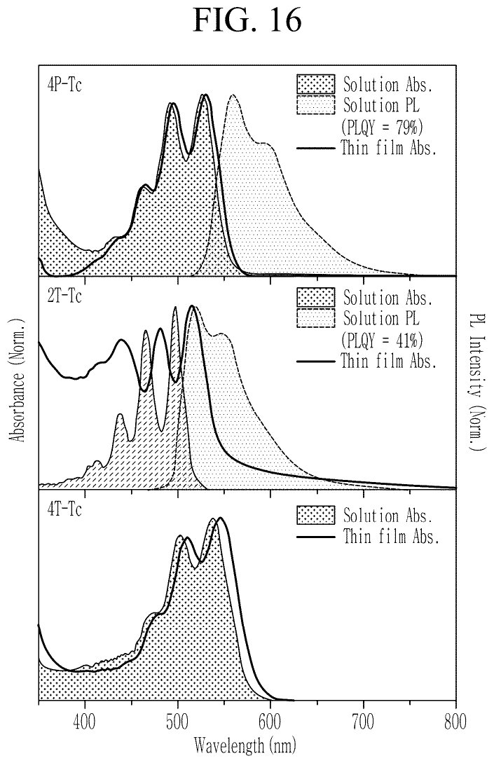

Steady-state absorption spectra and photoluminescence (PL) spectra of the prepared solutions and thin films were measured, and the results are described in FIG. 16. FIG. 16 shows graphs of the absorption spectra and PL spectra of rubrene (4P-Tc), and 2T-Tc and 4T-Tc, prepared in Synthesis Examples 1 and 2, respectively, in solution state and in thin films.

Steady-state absorption spectra were measured on a UV/Vis/NIR spectrometer (Varian, Cary 5000), and PL spectra were measured on a fluorescence spectrophotometer (Hitachi, F-7000). Photoluminescence (PL) spectra are spectrally corrected by using the correction factor of the fluorescence spectrophotometer. All solutions used in PLQY calculation were prepared with an absorbance of under 0.1 in 0-0 band by adjusting concentrations of each of 4P-Tc, 2T-Tc, and 4T-Tc, degassing, and dilution to minimize inner-filter effects, and the measurement was performed with respect to Rhodamine 6G in ethanol (λ_{exc}=460 nm) as a standard material.

Referring to FIG. 16, in solution, 4P-Tc exhibits distinct vibronic features in its absorption and PL spectra, with an intersection at 542 nm (2.29 eV). Its PL quantum yield (PLQY) is estimated to be approximately 0.8, consistent with previous findings. The 2T-Tc solution shows a hypsochromic shift in both its absorption and PL spectra, with an intersection at 505 nm (2.45 eV), indicating an enlarged HOMO-LUMO gap due to the reduced number of electron-donating substituents on the tetracene core. The PLQY of 2T-Tc in toluene is around 0.4, slightly lower than that of 4P-Tc due to triplet formation via intersystem crossing (ISC) induced by the thiophene substituents (discussed below). In the case of 4T-Tc, the absorption spectrum again shows bathochromic shifts, with peak positions located at a slightly lower energy side compared to those of 4P-Tc. Highly weak PL signals for 4T-Tc in toluene were detected, which is attributed to fast internal conversion from S1 to S0, rather than ISC, despite the presence of additional thienyl substituents compared to 2T-Tc.

A notable difference among the three compounds is the broadness of the absorption peaks: 2T-Tc displays narrow vibronic features, while 4P-Tc and 4T-Tc exhibit broader peaks. This can be explained by core distortion, a similar phenomenon previously observed in perylene bisimide derivatives, where the twisting motion of a distorted core induces inhomogeneous broadening. This suggests that 4P-Tc and 4T-Tc have distorted tetracene planes in the ground state due to the steric congestion caused by the tetraphenyl and tetrathienyl substituents, respectively. In contrast, 2T-Tc likely maintains a planar tetracene core due to the absence of such steric hindrance. The PL spectrum of 2T-Tc becomes significantly broader compared to its absorption spectrum, hinting at additional structural flexibility in the S1 state.

### (3) Computational Analysis (Density Functional Theory)

Density functional theory (DFT) simulations were performed using Gaussian16 software. The single molecules were optimized in the gas phase using B3LYP4 functional and DGDZVP5 basis set to obtain the lowest energy conformation. Time-dependent DFT was carried out with the M062X functional and Def2TZVP basis set in toluene, which is in reasonable agreement with the experimental vertical S1 and T1 values of the singlet fission material.

DFT calculations provided deeper insight into the steady-state optical and structural properties of the three compounds, as well as the feasibility of SF (singlet fission) in 2T-Tc and 4T-Tc from an energetic perspective, as shown in Table 3 below. As previously reported, 4P-Tc exhibits a twisted geometry in the ground state, and 4T-Tc displays a similar degree of core twisting, indicating the influence of steric interactions between the substituents. In contrast, 2T-Tc maintains a flat tetracene core, consistent with the steady-state absorption data discussed earlier. Regarding the energy levels of the frontier molecular orbitals, 4P-Tc shows the shallowest HOMO and LUMO levels. While the HOMO-LUMO energy gap of 4T-Tc is comparable to that of 4P-Tc, its energy levels are deeper, suggesting that thienyl substituents have a weaker electron-donating ability compared to phenyl groups. 2T-Tc exhibits a deeper HOMO, but a shallower LUMO than 4T-Tc, likely due to a combination of the differing number of thienyl substituents and the core distortion effects. Since the S₀→S₁ transitions in all compounds are primarily derived from the HOMO and LUMO orbitals, the vertical transition energies of the S1 states follow the trend in HOMO-LUMO gaps (2T-Tc>4P-Tc>4T-Tc). Additionally, a comparison of the energy gaps between the S1 and T₁ states shows that all compounds could undergo endothermic SF, irrespective of whether the vertical (Franck-Condon) or adiabatic (relaxed) energies are considered. Nevertheless, it is worth noting that 2T-Tc has a larger endothermicity of energetics of SF due to the smaller number of substituents compared to other tetracene derivatives.

TABLE 3

| | Core | | | | | | | | |
|---|---|---|---|---|---|---|---|---|---|
| | twist | | | | | | | | |
| | angle, | | | | | | | E(S_{1, v}) − | E(S_{1, a}) − |
| | θ | HOMO | LUMO | S_{1, v} | T_{1, v} | S_{1, a} | T_{1, a} | 2E(T_{1, v}) | 2E(T_{1, a}) |
| | (°) | (eV) | (eV) | (eV) | (eV) | (eV) | (eV) | (eV) | (eV) |
| 4P-Tc | 43.05 | −4.92 | −2.41 | 2.39 | 1.25 | 1.95 | 1.01 | −0.11 | −0.07 |
| 2T-Tc | 0.01 | −5.19 | −2.54 | 2.58 | 1.38 | 2.18 | 1.14 | −0.18 | −0.1 |
| 4T-Tc | 43.81 | −5.10 | −2.69 | 2.31 | 1.20 | 1.88 | 0.96 | −0.09 | −0.04 |

### (4) Computational Analysis (Molecular Dynamics Simulations)

The amorphous structure used for molecular structure analysis was generated by molecular dynamics (MD) simulation. The MD simulation was performed using the Desmond package (Schrodinger, LLC, NY, USA) with an Optimized Potentials for Liquid Simulations (OPLS) force field, which is commonly used for organic molecules. The initial structure was generated with 700 randomly placed molecules. After a brief Brownian minimization step of 100 ps at 10K, the amorphous structure was generated by a heating and cooling process under the NPT ensemble, specifically, after a heating period of 5 nanoseconds (ns) at 500 K, the system was cooled to 300 K with a 50K interval for 4 ns, and then held at 300 K for another 5 ns.

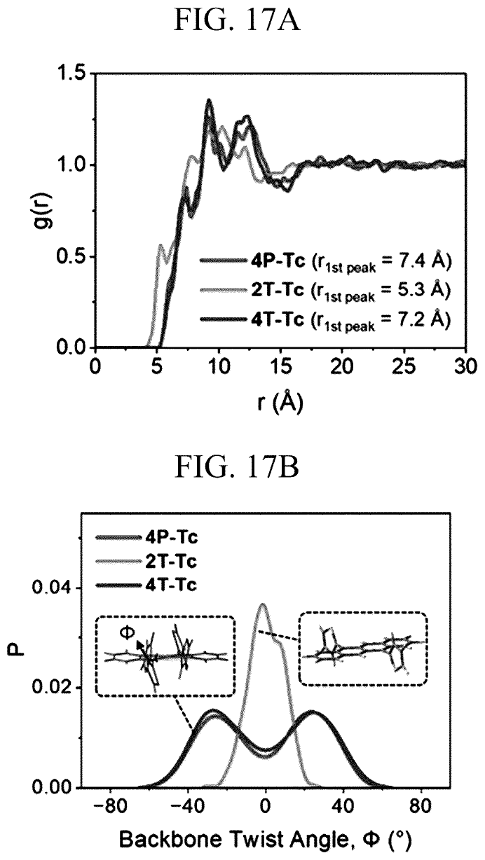

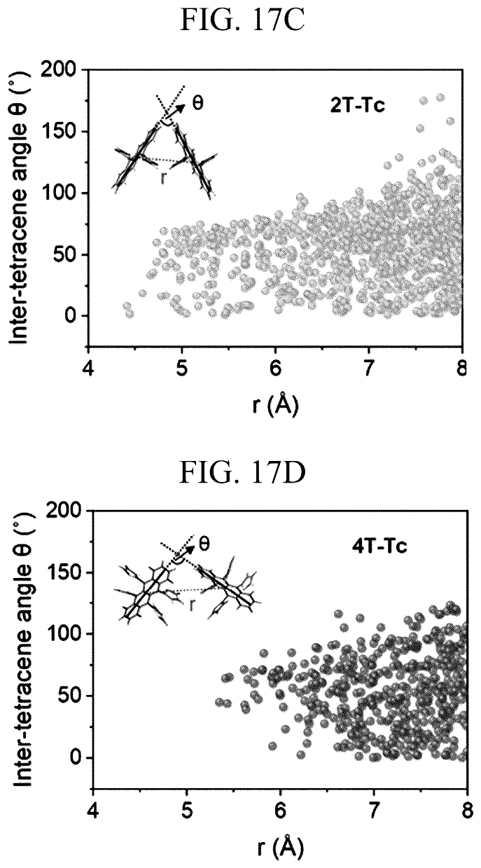

Further referring to FIG. 16, in thermally evaporated thin films, 4P-Tc and 4T-Tc exhibit absorption spectra nearly identical to their solution-phase counterparts, with only slight red shifts. This suggests that both compounds form amorphous films, characterized by relatively weak intermolecular interactions. In contrast, 2T-Tc displays significant red shifts and notable changes in the distribution of its vibronic progressions, indicating stronger and more distinct intermolecular interactions in the thin-film. To further investigate the differences in solid-state packing behavior among these three tetracene derivatives in thermally evaporated thin films, we performed molecular dynamics (MD) simulations, with the results shown in FIG. 17A to FIG. 17D.

FIG. 17A is radial distribution functions between the center-of-mass coordinates, and FIG. 17B is probability distribution of backbone twist angle for 4P-Tc, 2T-Tc, and 4T-Tc in the MD simulation results.

Referring to FIG. 17A, the radial distribution function g(r) plot for 2T-Tc shows an intense first peak at 5.3 A, consistent with values observed both theoretically and experimentally for bare tetracene, suggesting that 2T-Tc forms crystalline domains due to its planar backbone. In contrast, 4T-Tc exhibits a first peak at 7.2 A, similar to 4P-Tc, which has a peak at 7.4 A, indicating that the distance between the nearest-neighbor molecules is much longer than 2T-Tc due to their twisted backbones and the steric effects of the aryl substituents. The g(r) plot also correlates with the probability distribution of tetracene backbone twist angles in the simulation results. As shown in FIG. 17B, 2T-Tc shows a narrow distribution centered around 0°, while 4P-Tc and 4T-Tc display broader distributions centered around 35°, with each center value corresponding to the DFT-optimized structures. This implies that the number of planar molecules in the thin films of 2T-Tc is significantly greater than in those of 4P-Tc or 4T-Tc.

Furthermore, referring to FIG. 17C and FIG. 17D, distribution plots as a function of inter-tetracene angle and center-of-mass distance between neighboring molecules of 2T-Tc and 4T-Tc suggest, owing to its planar core, 2T-Tc thin film is better positioned to form a “sweet spot” with small inter-tetracene angles and distances, where intermolecular interactions could be maximized. Overall, the MD simulation results indicate that the backbone structures and steric effects of the aryl substituents are critical factors in determining the solid-state packing structures of thermally evaporated thin films for tetracene derivatives.

### (5) Femtosecond and Nanosecond Transient Absorption Spectroscopy

Next, we investigated the excited-state dynamics of the monomeric forms of the three tetracene derivatives using femtosecond (fs) and nanosecond (ns) transient absorption (TA) spectroscopy.

A Ti (titanium): Sapphire regenerative amplifier system (800 nm, 350 μJ, 10 kHz, 35 fs, Spitfire Pro, Spectra Physics) was used as a fundamental laser source of femtosecond transient absorption (fs-TA) spectrometer. First, fundamental pulses were divided into two parts by a 5:5 (R:T) beam splitter. A half portion of fundamental pulses consisted of optical parametric amplifiers (TOPAS C, Spectra Physics). The other portion was attenuated by a combination of irises and a neutral density filter and used for the generation of white light continuum (WLC) probe pulses by using a 4 mm calcium fluoride window (EKSMA optics). The time delay between pump and probe beams was controlled by a linear motor stage (ILS300LM-S, Newport) in the beamline for a probe generation stage. Spectra of the dispersed WLC probe are monitored by a high-speed spectrometer (Ultrafast Systems). Due to the limit of camera frame rate, we obtained TA spectra with a rate of 2 kHz. For this, the pump pulses were modulated at 1 kHz by an optical chopper (MC2000B for a controller, MC1F10 for an optical chopper blade, Thorlabs). Thus, the detection procedure involves measuring five consecutive laser pulses to generate one TA spectrum. In each scan, we averaged 1500 TA spectra to secure an acceptable signal-to-noise ratio. Furthermore, five individual scans were carried out to reduce the long-term fluctuation of the laser. To prevent polarization-dependent signals, the polarization angle of the pump pulse was set at the magic angle (54.7°) to the horizontally polarized probe pulse using a Glan-laser calcite polarizer (GL10-A, Thorlabs) and an achromatic half-wave plate (AQWP05M-600, Thorlabs). All experiments were done with 480 nm excitation (pump fluence=19 μJ/cm²).

Nanosecond transient absorption (TA) measurements were performed with an automated transient absorption spectrometer (EOS, Ultrafast Systems), driven by the diode pumped Q-switched Nd:YAG laser and OPO (NT242, EKSPLA) operating at 1 kHz. Supercontinuum laser operating at 2 kHz was used for the nanosecond TA experiments and time delays were electronically controlled. The OPO (NT242, EKSPLA) generates a 5 cm⁻¹ narrow linewidth pump pulse and 3-6 ns pulse duration. The sample was excited at 480 nm wavelength with an energy of 400 nJ. A quartz cell with a 2 mm path length (21/Q/2, Starna) was employed. All experiments were done with 480 nm excitation (pump fluence=149 μJ/cm²).

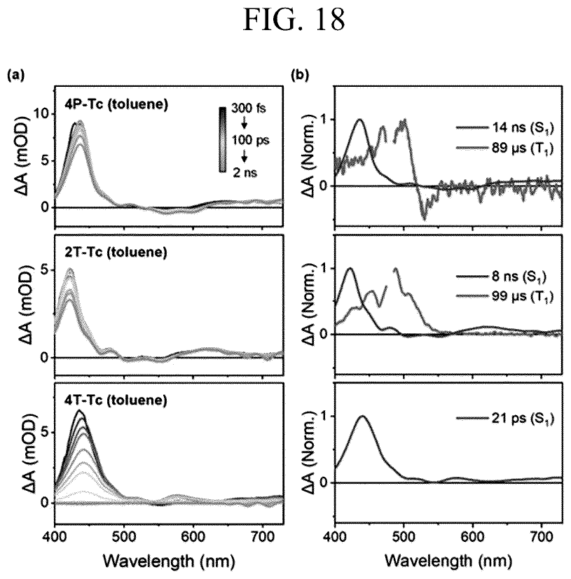

FIG. 18 shows graphs representing the results of femtosecond transient absorption (fs-TA) of the thermally evaporated thin films of Rubrene (4P-Tc), 2T-Tc, and 4T-Tc.

Referring to FIG. 18(a), immediately after photoexcitation, both 4P-Tc and 2T-Tc exhibit strong and weak photoinduced absorption (PIA) bands around 400-450 nm and 600-750 nm, respectively. Additionally, relatively weak ground-state bleach (GSB) and stimulated emission (SE) signals are observed in regions consistent with their steady-state absorption and PL spectra. From 300 fs to 2 ns, both 4P-Tc and 2T-Tc show minimal spectral evolution, primarily reflecting S₁ decay.

Further characterization of the excited-state dynamics was carried out using ns-TA experiments, revealing that most of the excited-state population in both compounds undergoes ground-state recovery, with a minor fraction forming the T₁ state via intersystem crossing (ISC). The time constants for the S₁ decay were determined to be 14 ns for 4P-Tc and 8 ns for 2T-Tc (FIG. 18(b)). The T₁ absorption spectra for both compounds appear in similar wavelength ranges, from 400 to 550 nm, with T₁ lifetimes estimated at 89 ps for 4P-Tc and 99 ps for 2T-Tc. The relative T₁ yield of 2T-Tc is notably higher than that of 4P-Tc, likely due to the presence of thienyl substituents, which typically enhance spin-orbit coupling. Interestingly, despite having a greater number of thienyl substituents, 4T-Tc only exhibits rapid internal conversion with a time constant of 21 ps (FIG. 18(b)), and no T₁ state formation is observed, as previously reported. Without wanting to be bound by a particular theory, it is proposed that the structural flexibility of 4T-Tc in solution enables non-radiative decay pathways, which may correlate with the distinct PL signals observed in thin films. However, the detailed mechanism of this behavior is not related to the scope of this work and will be reported elsewhere.

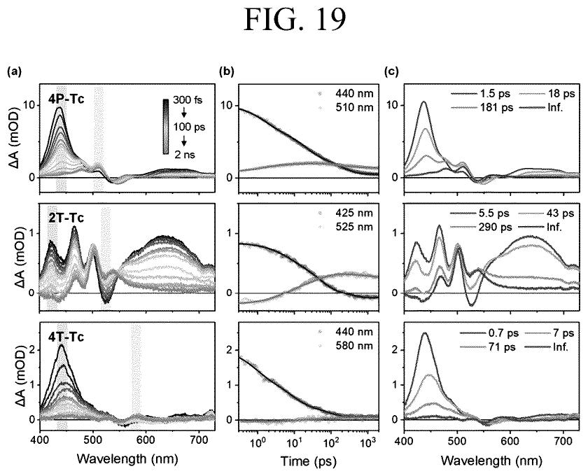

FIG. 19 presents the fs-TA results for as-prepared thermally evaporated thin films of the three tetracene derivatives, excited at 480 nm. Initially, 4P-Tc shows a strong PIA band at 435 nm and a broader, weaker PIA band around 650 nm, similar to the spectra observed in toluene, indicating that these signals originate from the S₁ state. However, unlike the dynamics observed in toluene, within 100 ps, the S₁ PIA decays and evolves into new spectral features, including vibronic PIA bands in the 450-530 nm range, which can be attributed to the formation of a triplet pair with singlet spin multiplicity, ¹(TT). The spectral shape of the ¹(TT) and the timescale of its formation closely resemble those previously observed in rubrene thin films and nanoparticles with amorphous packing structures. Importantly, the ¹(TT) formation dynamics do not follow simple monoexponential kinetics, suggesting the presence of multiple sub-ensembles exhibiting different interchromophoric interactions, likely due to the heterogeneous packing nature of the thin films. It is also important to note that the evolution-associated difference spectra (EADS) obtained from global analysis only reflect the timescale of spectral evolution (FIG. 19(c)), without identifying individual species or electronic states, as the excited-state dynamics in thin films do not originate from a single ensemble, unlike in simple solution-phase or single crystal experiments. As will be discussed in more detail below with the decay-associated difference spectra (DADS), as shown in FIG. 19(c), the first and second components (τ1=1.5 ps and τ2=18 ps) are associated with the formation of ¹(TT), while the third component (τ3=181 ps) corresponds to the S₁ decay from a sub-ensemble that does not undergo SF. The final component represents the long-lived ¹(TT) population originating from the first and second components.

For 4T-Tc, the spectral features, their evolution, and the dynamics are quite similar to those observed in 4P-Tc. Notably, while the long-lived component was absent in the solution phase of 4T-Tc, it appears in the thin film phase, suggesting that the ¹(TT) formation channel is activated due to intermolecular interactions in the thin films. The first component (τ1=0.7 ps) corresponds to S₁ decay from a sub-ensemble that does not undergo ¹(TT) formation (see below). In contrast, the second and third components (τ2=7 ps and τ3=71 ps) are attributed to parallel ¹(TT) formation dynamics from multiple sub-ensembles, with the long-lived ¹(TT) species appearing as an infinite component.

In 2T-Tc, the initial TA spectrum at 300 fs shows significant deviation from that observed in toluene solution, indicating perturbed S₁ states due to strong intermolecular interactions, which is consistent with its polycrystalline nature. Unlike 2T-Tc in toluene, but similar to 4P-Tc and 4T-Tc thin films, the S₁ ESA decays within approximately 200 ps, accompanied by a rise in signals around 525 nm. The final spectrum, with ESA spanning 450 to 600 nm, resembles the T₁ absorption spectrum observed in solution, indicating that ¹(TT) is ultimately formed. Global analysis yielded three time constants, excluding the infinite component. The first two time constants (τ1=5.5 ps and τ2=43 ps) correspond to ¹(TT) formation, while the third constant (τ3=290 ps) is attributed to S₁ decay from a sub-ensemble that does not undergo SF. The slower time constants for ¹(TT) formation of 2T-Tc compared to 4P-Tc.

To estimate the ¹(TT) yields in thin films, we further analyzed the fs-TA results using DADS, focusing purely on the kinetics and accounting for the intrinsically heterogeneous nature of the films, which contain multiple sub-ensembles. While several methods exist for calculating ¹(TT) yields—such as singlet depletion or sensitization yield determination—we did not adopt these approaches, which are typically used in solution-phase experiments, for the following reasons. First, laser-induced thermal artifacts can alter the refractive index of thin films, producing transient spectra near the ground-state absorption region that persist for up to a ps. This can skew the results and lead to an overestimation of triplet yields. Additionally, unlike solution-phase experiments involving molecular dimers, exciton-exciton annihilation—acting as a population loss channel—can influence early-time kinetics in thin films. This factor would likely result in an underestimation of the final triplet yields.

In the spectral evolution of all thin films, particularly during the ¹(TT) formation, we observed multiple isosbestic points above the baseline, indicating quantitative ¹(TT) formation without losses due to ground-state recovery. These spectral changes are reflected as negative amplitudes for the ¹(TT) rise and positive amplitudes for the S₁ decay in the DADS. Moreover, each kinetic process involves different isosbestic points, strongly suggesting that ¹(TT) formation originates from multiple sub-ensembles rather than a single one.

By estimating the ratio between the amplitudes of the S₁ decay regions, we can approximate the maximum ¹(TT) yields. Among the three derivatives, 2T-Tc exhibits the highest ¹(TT) yield (78.3%), followed by 4P-Tc with a slightly lower yield (73.0%), and 4T-Tc with the lowest yield (51.2%). It is important to note that the initial exciton-exciton annihilation processes are not precisely considered in this analysis, resulting in a slight overestimation of the ¹(TT) yield. Assuming all ¹(TT) species dissociate into free triplets (T₁+T₁) through spatial separation and spin decorrelation without ground-state recovery, the upper limit of free triplet yields could also be estimated to be twice the ¹(TT) yields. However, the actual free triplet yields are expected to be lower than this theoretical limit due to the active reverse process, i.e., triplet-triplet annihilation via Dexter-type energy transfer, in thin films.

Typically, the evolution from ¹(TT) to ¹(T . . . T), which signifies electronic decoherence through triplet hopping, is observed in thin films of SF chromophores. This process generally occurs on a picosecond timescale and is characterized by changes in the vibronic peak ratios in the PIA spectra. However, this transition is somewhat unclear in our results, likely due to weaker inter-triplet electronic coupling compared to the coupling between ¹(TT) and the phonon bath. It is well-established that, in such cases, the distinction between ¹(TT) and ¹(T . . . T) can be negligible. Therefore, we do not differentiate between ¹(TT) and ¹(T . . . T) in this study. Following the formation of ¹(TT), all thin films exhibit multiphasic triplet decay kinetics, extending up to tens of microseconds. We found that the timescale of this decay is much shorter than the T₁ lifetime in solution and is also similar to the delayed PL kinetics, suggesting its origin in triplet-triplet annihilation (TTA), including both geminate and non-geminate processes. As discussed earlier, multiple sub-ensembles are likely present in all thin films, so these TTA processes could occur in different sub-ensembles. Additionally, while transient signals in the TA spectra due to thermal artifacts could contribute to long-lived features in the ns-to-ps range, we propose that triplet signals are the primary contributors to the overall spectra, considering that the delayed PL signals likely originate from TTA.

### (6) Evaluation of Physical and Chemical Stabilities of the Thin Films

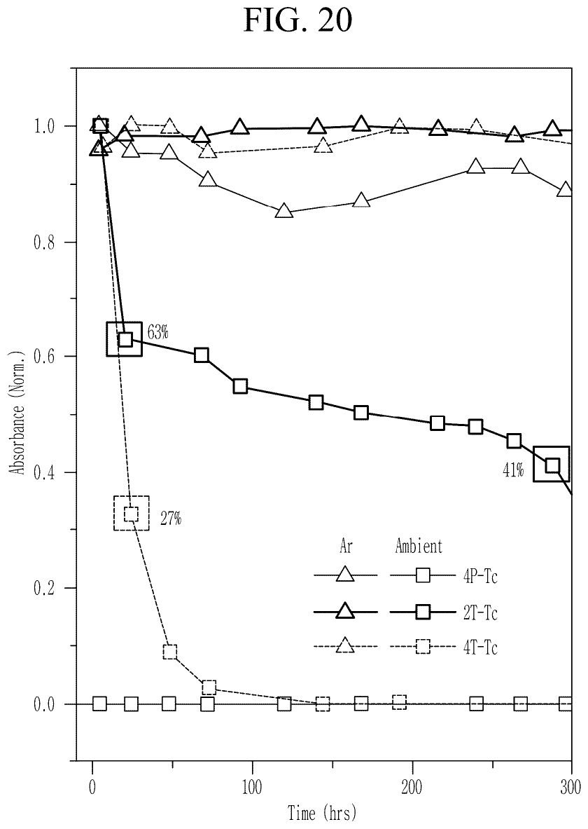

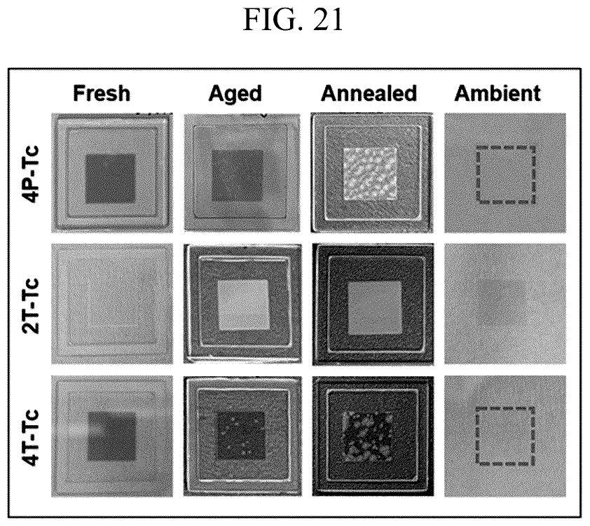

In addition to analyzing SF dynamics, we further examined the physical and chemical stabilities of the thin films for their potential optoelectronic applications. First, encapsulated thin films were prepared, and we monitored absorbance (at the peak maximum of the 0-0 band of S₁) and physical changes over a period of up to 300 hours (12.5 days). As shown in FIG. 20, the 2T-Tc thin film showed no changes in absorbance over time, whereas 4P-Tc and 4T-Tc thin films exhibited slight fluctuations. Notably, as shown in FIG. 21, both 4P-Tc and 4T-Tc began to form pale spots within a few days, and this growth was accelerated with thermal annealing. Previous reports have indicated that amorphous 4P-Tc thin films readily undergo crystallization into radially disk-like domains, indicating that the crystalline phase is thermodynamically more stable than the amorphous phase. Furthermore, the absorption spectra of crystallized domains differ from those of the original amorphous films, indicating that the absorbance fluctuations are due to phase transformation rather than chemical decomposition.

We further confirmed that fs- and ns-TA and time-resolved PL results for phase-transformed domains align well with previous findings for polycrystalline rubrene thin films. The phase transition in 4T-Tc thin films occurred slightly more slowly than in 4P-Tc but followed the same trend, with similar time-resolved optical properties. In sharp contrast, 2T-Tc thin films displayed no changes in morphology, even after prolonged aging and thermal annealing, suggesting that the absence of further crystallization or phase transformation is due to the planar tetracene backbone of 2T-Tc. This intrinsic stability allows 2T-Tc to form thermodynamically stable polycrystalline structures in thin films from the outset, preventing further phase transitions. Phase stability in thin films is crucial for maintaining the consistent performance of optoelectronic devices; thus, 2T-Tc appears highly advantageous in this regard.

From a chemical stability perspective, we further assessed the durability of the thin films after exposure to ambient air. Notably, as shown in FIG. 21, a 4P-Tc thin film became transparent just within 5 minutes, likely due to the formation of endoperoxide or epoxide. We found that 4T-Tc exhibited better chemical stability than 4P-Tc, retaining 30% of its initial absorbance after one day and fully degrading after three days. Intriguingly, the normalized absorbance of 2T-Tc initially dropped to 63% after one day, but its rate of degradation was significantly slower than that of 4P-Tc and 4T-Tc. 2T-Tc retained 41% of its absorbance after 12.5 days (FIG. 20), and even after four months, the film remained visibly yellow (FIG. 21), suggesting far superior resistance to oxygen and moisture compared to the others.

This behavior contrasts with the chemical stability observed in ambient solution; in solution, 4T-Tc is highly stable, whereas 4P-Tc and 2T-Tc gradually degrade. In solution, the S₁ lifetime plays a significant role in chemical stability, as a shorter lifetime reduces the likelihood of molecules encountering dissolved molecular oxygen. However, in thin films, packing density more strongly influences air and moisture durability, as voids within the film can allow oxygen and moisture penetration. Since 4P-Tc and 4T-Tc initially form amorphous phases, their chemical stability is likely reduced due to this increased permeability. Conversely, 2T-Tc, which forms a densely packed polycrystalline phase owing to the planar backbone from the outset, demonstrates enhanced chemical stability owing to its compact structure in polycrystalline domains. However, we found that backbone planarity alone does not determine the chemical stability of thin films. We also fabricated a thin film using the previously reported 5,12-di(thiophen-2-yl)tetracene, but it degraded within a few minutes (data not shown), suggesting that achieving both backbone planarity and suppressed chemical reactivity of the tetracene core through suitable substituents is essential for producing stable organic thin films.

Consequently, these results suggest that in molecular engineering for optoelectronic devices, molecular planarity controlled by proper peripheral substituents stabilizing electronic structures of backbones, i.e., the balance between the two factors is a crucial consideration, as it significantly impacts the physical and chemical properties of the resulting thin films.

### (7) Time-Resolved Photoluminescence Spectroscopy

Time-resolved photoluminescence (TRPL) spectra were measured using an ICCD detector (PI MAX4, Princeton Instruments) after photoexcitation by a 480 nm pump beam from an optical parametric oscillator (OPO, NT242, EKSPLA). To accurately measure the PL changes over time, we recorded the dynamics in shorter segments, keeping the gate width and changing the gate delay constant within each segment. The gate width was always less than the gate step. For each segment, the gain of intensifier and number of on-CCD accumulations were controlled to increase signal intensity. Overlaps were included between the end of one segment and the start of the next to ensure continuity. Background spectra were also measured for each segment.

### Example 1: Manufacture of Sensor

ITO is deposited on a glass substrate to form a 150 nm-thick anode (work function: 4.9 eV). Subsequently, on the anode, N-[1,1′-Diphenyl]-4-yl-9,9-dimethyl-N-[4-(9-phenyl-9H-carbazol-3-yl)phenyl]-9H-fluorene-2-amine (HT211) is thermally deposited to form a 15 nm-thick hole auxiliary layer (HOMO: 5.35 eV, LUMO: 2.08 eV). Then, the singlet fission material 2T-Tc, synthesized in Synthesis Example 1, was thermally deposited on the hole auxiliary layer to form a 50 nm-thick organic auxiliary layer (HOMO: 5.19 eV, LUMO: 2.54 eV). Subsequently, Compound P (p-type semiconductor) and fullerene (C60, n-type semiconductor) in a volume ratio (thickness ratio) of 1:1 are co-deposited thereon to form a 50 nm-thick photoelectric conversion layer. Then, 2,9-Dimethyl-4,7-diphenyl-1,10-phenanthroline (BCP) is thermally deposited thereon to form a 5 nm-thick electron auxiliary layer, and ITO is deposited thereon to form a 7 nm-thick cathode (work function: 4.7 eV), manufacturing a sensor.

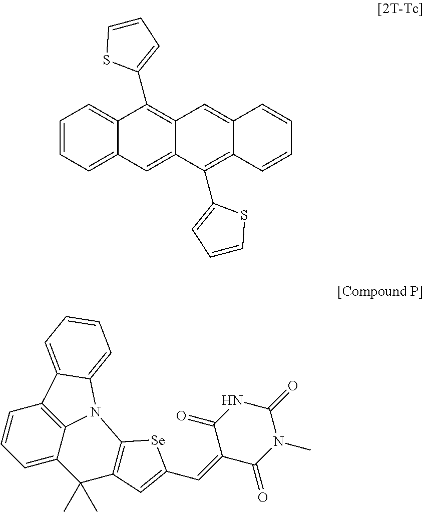 [SMILES: c1csc(-c2c3ccccc3cc3c(-c4cccs4)c4ccccc4cc23)c1 ; CN1C(=O)NC(=O)/C(=C\c2cc3c([se]2)-n2c4ccccc4c4cccc(c42)C3(C)C)C1=O]

### Comparative Example 1: Manufacture of Sensor

A sensor is manufactured in the same manner as in Example 1, except that the 50 nm-thick organic auxiliary layer is not formed.

### Evaluation

The sensors according to Example 1 and Comparative Example 1 are evaluated with respect to the external quantum efficiency (EQE) and internal quantum efficiency (IQE) according to the methods described below, and the results are shown in Table 4.

The EQEs of the sensors are evaluated by using Incident Photon to Current Efficiency (IPCE), which measures the ratio of photocurrent to the number of incident photons as a function of wavelengths.

The IQEs of the sensors are determined by measuring absorbances, A, of the sensors, followed by dividing EQEs by the measured A. The absorbance, A, may be obtained by the Relation Formula 2 below.

### Relation Formula 2

$$A = 100 - T - R$$

In Relation Formula 2, A is absorbance, T is transmittance, and R is reflectance. The transmittance (T) and reflectance (R) may be determined by using UV-Vis spectrometer (Shimadzu Corporation Ltd.).

TABLE 4

| | EQE | | IQE | |
|---|---|---|---|---|
| | EQE@3 V | λₘₐₓ | IQE@3 V | λₘₐₓ |
| | (%) | (nm) | (%) | (nm) |
| Comparative Example 1 | 46.81 | 520 | 82.12 | 535 |
| Example 1 | 53.76 | 530 | 94.14 | 535 |

In Table 4, Δₘₐₓ indicates that the wavelengths at which maximum external quantum efficiency (EQE) and maximum internal quantum efficiency (IQE) are exhibited.

Referring to Table 4, the sensor according to Example 1, compared with the sensor according to Comparative Example 1, exhibits an improved external quantum efficiency (EQE) and internal quantum efficiency (IQE). Accordingly, the sensor according to Example 1 may be expected to implement improved sensitivity in a relatively narrow wavelength region.

While the inventive concepts have been described in connection with what is presently considered to be practical example embodiments, it is to be understood that the inventive concepts are not limited to such example embodiments. On the contrary, the scope of the inventive concepts is intended to cover various modifications and equivalent arrangements included within the spirit and scope of the appended claims.

What is claimed is:

1. A sensor, comprising:
an anode;
a cathode;
an organic photoelectric conversion layer between the anode and the cathode, the organic photoelectric conversion layer including a p-type semiconductor and an n-type semiconductor; and
a first organic auxiliary layer between the anode and the organic photoelectric conversion layer, the first organic auxiliary layer including a first singlet fission material,
wherein the first singlet fission material is represented by Chemical Formula 1 and satisfies Relation Formula 1: 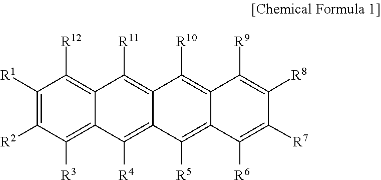
wherein, in the Chemical Formula 1,
R¹ to R¹² are each independently hydrogen, deuterium, a substituted or unsubstituted C1 to C30 alkyl group, a substituted or unsubstituted C1 to C30 alkoxy group, a substituted or unsubstituted C6 to C30 aryl group, a substituted or unsubstituted C3 to C30 heteroaryl group, a substituted or unsubstituted silyl group, a substituted or unsubstituted amine group, a halogen, a cyano group, or any combination thereof, provided that at least one of R¹ to R¹² is represented by Chemical Formula 2: 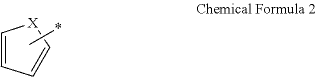
wherein, in Chemical Formula 2,
X is oxygen, sulfur, or tellurium, and
* is a linking point with Chemical Formula 1; and
$$E ( {S}_{1} ) + 0.5 eV \geq 2 \times E ( {T}_{1} ) , \qquad Relation Formula 1$$
wherein, in Relation Formula 1,
E(S₁) is an excitation energy in a lowest singlet excited state of the first singlet fission material,
E(T₁) is an excitation energy in a lowest triplet excited state of the first singlet fission material, and
E(S₁) and E(T₁) are Density Function Theory calculation values.

2. The sensor of claim 1, wherein a highest occupied molecular orbital (HOMO) energy level of the first singlet fission material is a same or shallower energy level relative to a HOMO energy level of the p-type semiconductor.

3. The sensor of claim 1, wherein first organic auxiliary layer is in contact with the organic photoelectric conversion layer.

4. The sensor of claim 1, wherein a HOMO energy level of the first singlet fission material is between a HOMO energy level of the p-type semiconductor and a work function of the anode.

5. The sensor of claim 1, wherein the first singlet fission material and at least one of the p-type semiconductor or the n-type semiconductor are each a wavelength-selective organic material configured to selectively absorb light of a first wavelength spectrum selected from a blue wavelength spectrum, a green wavelength spectrum, a red wavelength spectrum, or an infrared wavelength spectrum.

6. The sensor of claim 1,
wherein in Chemical Formula 1, at least one of R³ to R⁶ and at least one of R⁹ to R¹² are, each independently, represented by Chemical Formula 2, or,
wherein, in Chemical Formula 1, at least one of R¹ and R² and at least one of R⁷ to R⁸ are, each independently, represented by Chemical Formula 2.

7. The sensor of claim 1, wherein the first singlet fission material is represented by any one of Group 1:

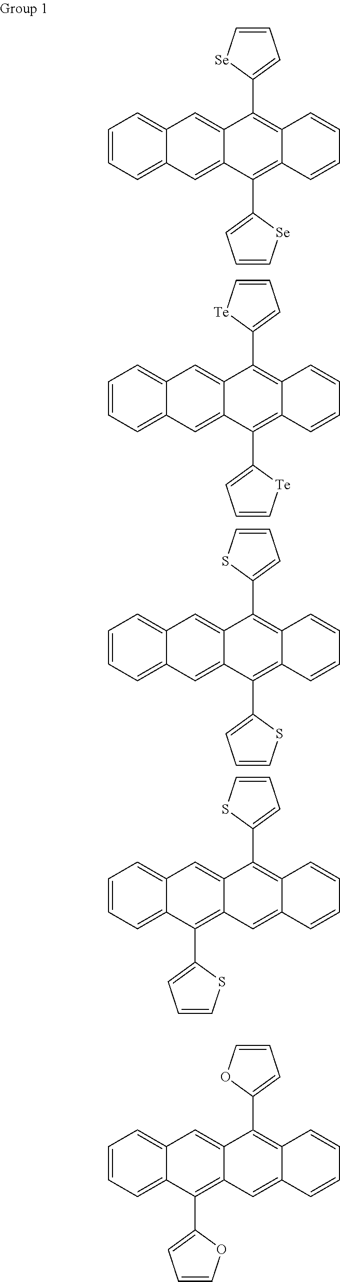

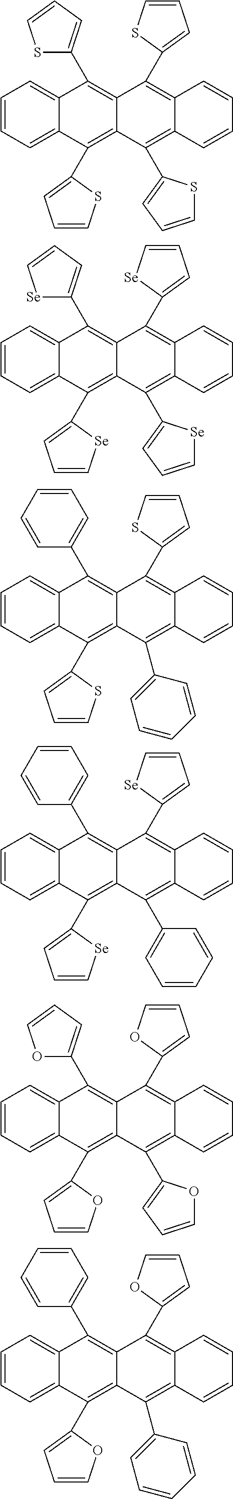

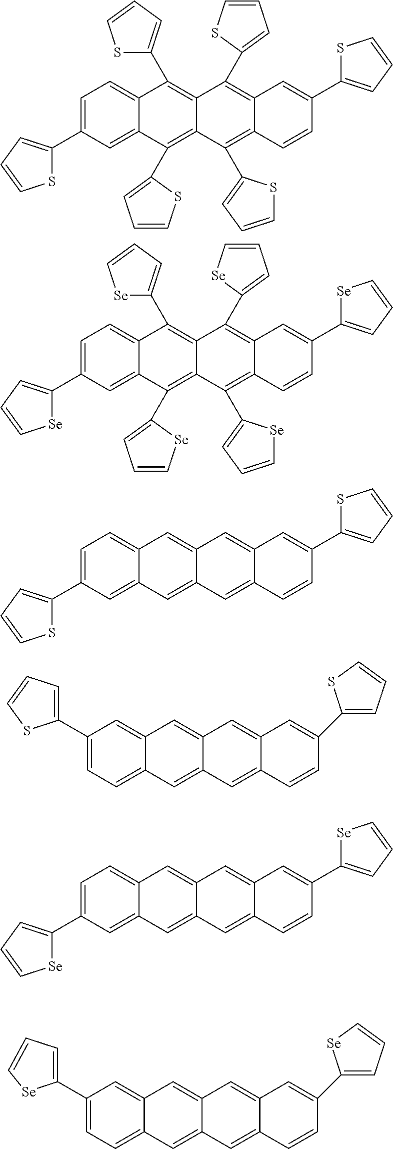

8. The sensor of claim 1, further comprising:
a hole auxiliary layer between the first organic auxiliary layer and the anode,
wherein a lowest unoccupied molecular orbital (LUMO) energy level of the hole auxiliary layer is a shallower energy level relative to a work function of the anode and a LUMO energy level of the n-type semiconductor.

9. The sensor of claim 1, further comprising:
a second organic auxiliary layer between the cathode and the organic photoelectric conversion layer,
wherein the second organic auxiliary layer comprises a second singlet fission material different from the first singlet fission material.

10. The sensor of claim 9, wherein
the second organic auxiliary layer is in contact with the organic photoelectric conversion layer, and
a LUMO energy level of the second singlet fission material is a same or deeper energy level relative to a LUMO energy level of the n-type semiconductor.

11. The sensor of claim 9, wherein
a LUMO energy level of the second singlet fission material is between a LUMO energy level of the n-type semiconductor and a work function of the cathode.

12. The sensor of claim 9, further comprising:
an electron auxiliary layer between the second organic auxiliary layer and the cathode,
wherein a HOMO energy level of the electron auxiliary layer is a deeper energy level relative to a work function of the cathode and the HOMO energy level of the p-type semiconductor.

13. An image sensor, comprising:
a substrate, and
the sensor of claim 1 on the substrate.

14. The image sensor of claim 13, further comprising:
a first photodiode and a second photodiode within the substrate,
wherein the first photodiode and the second photodiode each overlap the sensor along a thickness direction of the substrate.

15. The image sensor of claim 14, further comprising:
a first color filter between the sensor and the first photodiode in the thickness direction, and
a second color filter between the sensor and the second photodiode in the thickness direction.

16. The image sensor of claim 13, wherein the sensor comprises:
a first sensor configured to photoelectrically convert light of a first wavelength spectrum selected from a red wavelength spectrum, a green wavelength spectrum, and a blue wavelength spectrum,
a second sensor configured to photoelectrically convert light of a second wavelength spectrum selected from the red wavelength spectrum, the green wavelength spectrum, and the blue wavelength spectrum, and
a third sensor configured to photoelectrically convert light of a third wavelength spectrum selected from the red wavelength spectrum, the green wavelength spectrum, and the blue wavelength spectrum,
wherein the first wavelength spectrum, the second wavelength spectrum, and the third wavelength spectrum are different from each other, and
wherein the first sensor, the second sensor, and the third sensor are stacked along a thickness direction of the substrate.

17. A display panel, comprising:
a substrate,
a light emitting element array on the substrate, the light emitting element array including:
a blue light emitting element configured to emit light in a blue wavelength spectrum,
a green light emitting element configured to emit light in a green wavelength spectrum, and
a red light emitting element configured to emit light in a red wavelength spectrum, and
a sensor array on the substrate, the sensor array including the sensor of claim 1.

18. A device comprising the sensor of claim 1.

19. A device comprising the image sensor of claim 13.

20. A device comprising the display panel of claim 17.
